(19) United States
(12) Patent Application Publication
(10) Pub. No.: US 2026/0092372 A1
(43) Pub. Date: Apr. 2, 2026

(54) CO-JET NOZZLE ASSEMBLY AND ANOMALY DETECTION

(71) Applicant: University of Notre Dame du Lac, South Bend, IN (US)

(72) Inventors: Yanliang Zhang, South Bend, IN (US); David Go, South Bend, IN (US); Yipu Du, South Bend, IN (US); Jinyu Yang, South Bend, IN (US)

(21) Appl. No.: 19/342,198

(22) Filed: Sep. 26, 2025

Related U.S. Application Data
(60) Provisional application No. 63/700,338, filed on Sep. 27, 2024.

(51) Int. Cl. C23C 16/455; B33Y 10/00; B33Y 30/00; B33Y 70/10; C23C 16/448; C23C 16/513; H01J 37/32; H05K 3/14

(52) U.S. Cl. CPC C23C 16/45576; B33Y 10/00; B33Y 30/00; B33Y 70/10; C23C 16/4486; C23C 16/45502; C23C 16/45557; C23C 16/513; H01J 37/32449; H01J 37/32926; H01J 37/32981; H01J 37/3299; H05K 3/146; H01J 2237/24592; H01J 2237/338; H05K 2203/095; H05K 2203/1131; H05K 2203/163

(57) ABSTRACT

A nozzle assembly may include a nozzle body defining a longitudinal axis, a central conduit extending through the nozzle body along the longitudinal axis, a first outer annular flow channel extending through the nozzle body, a first electrode positioned radially opposed to a second electrode with respect to the longitudinal axis, an aerosol generator body positioned upstream of the nozzle body, a first chamber formed in the aerosol generator body, a second outer annular flow channel extending through the aerosol generator body, the second outer annular flow channel concentrically surrounding the first chamber about the longitudinal axis, the second outer annular flow channel being radially outward from the longitudinal axis relative to the first chamber.

### CROSS-REFERENCE TO RELATED APPLICATION(S)

This application claims the benefit of U.S. Provisional Patent Application No. 63/700,338, filed on Sep. 27, 2024, the entire disclosure of which is incorporated by reference.

### STATEMENT OF GOVERNMENT INTEREST

This invention was made with government support under DE-EE0009103 awarded by the Department of Energy. The government has certain rights in the invention.

### TECHNICAL FIELD

The present disclosure relates to fluid delivery and deposition technologies and, more particularly, to multi-stream or co-jet nozzle assemblies for generating and directing particle-laden carrier gas streams for material deposition onto a substrate and related anomaly detection techniques.

### INTRODUCTION

Additive manufacturing is a fabrication approach that constructs three-dimensional structures by depositing material layer by layer. This process allows precise control over geometry, supports complex designs, and reduces material waste compared to subtractive techniques. Thus, additive manufacturing approaches expand design freedom and shorten development cycles, supporting new technologies in flexible and wearable electronics, human-machine interfaces, and connected devices, etc.

Aerosol-based printing represents one additive manufacturing technique tailored for electronic devices. Such processes use an aerosolized stream of functional inks to deposit material with high precision onto a substrate. Aerosol-based printing demonstrates distinct technical advantages. For example, this method may produce ultrafine features, process a wide range of materials, and support conformal and combinatorial printing. These attributes may support the construction of functional devices with properties not achievable through traditional fabrication methods.

In some examples, aerosol-based printing requires a post-printing sintering process. This step removes surfactants and binders and promotes atomic diffusion to form dense structures with desirable electrical conductivity. However, the sintering process may introduce challenges. For example, sintering processes may require significant time and thermal processing at elevated temperatures. Such conditions may limit the fabrication of metallic devices on temperature-sensitive substrates, including biological materials. Elevated temperatures may also restrict multi-material printing that integrates inorganic and organic materials.

To address the temperature restrictions of post-printing sintering, various alternative sintering techniques may be used. Such approaches aim to accelerate processing while reducing thermal stress on the substrate. In various implementations, flash sintering uses intense light pulses to consolidate deposited materials. Such approaches minimize thermal exposure of the underlying substrate. However, flash sintering processes remains thermally driven. Flash sintering involves heating of the printed material to a threshold temperature and still introduces additional processing time.

In other examples, chemical sintering relies on in situ chemical reactions to achieve particle bonding at low temperatures. Such approaches approach may reduce thermal demand but may be compatible with only specific inks and substrates. Chemical sintering also involves post-sintering cleaning of printed films, which introduces further complexity.

Non-thermal plasma sintering represents another approach for reducing thermal stress during material processing. Non-thermal plasma may refer to a partially ionized gas containing highly energetic electrons with energies in the range of about 1 to about 10 electron volts. The ions and neutral species may remain near ambient temperature, creating an overall low gas temperature. In various implementations, sintering is promoted by chemically reactive plasma species and photons rather than by bulk thermal effects.

In various implementations, multiple non-thermal plasma configurations are applied to sintering. Examples include low-pressure radio frequency plasmas, atmospheric pressure dielectric barrier discharge plasmas, and atmospheric pressure plasma jets. Plasma jets use a flowing working gas to extend the ionization zone and propagate plasma in a confined shape over a distance. This feature allows indirect, non-proximal plasma treatment. Plasma jets may be applicable for processing both metallic and polymer-based materials.

The use of a working gas flow in a plasma jet makes the approach suitable for integration with aerosol-based printing. Such integration supports in situ, low-temperature sintering of metallic inks at the point of printing. This process reduces the duration of post-printing treatments and supports continuous fabrication. However, some configurations introduce aerosol droplets directly into the plasma jet flow. The complex interactions between plasma and droplets, combined with the absence of dedicated mechanisms for precise aerosol deposition, create challenges for achieving effective sintering while preserving printing resolution.

Plasma jet printing may also introduce additional technical constraints. For example, initiating a plasma jet typically requires a voltage greater than 5 kilovolts. Additional insulation may be needed to prevent gas breakdown outside the aerosol flow. These factors complicate reactor design and limit flexibility in processing conditions.

### SUMMARY

Systems, apparatuses, methods, and techniques described herein address these and other technical challenges by implementing a co-jet printing method that integrate a particle (e.g., a nanoparticle ink) containing aerosol jet with a non-thermal atmospheric-pressure plasma jet in a coaxial configuration. Such techniques support direct and concurrent material deposition with in situ sintering at ambient temperature. Such processes may be applied to metal nanoparticle inks to achieve high resolution and conductivity on delicate substrates, including natural biological materials and soft polymers.

In various implementations, a machine learning-based real-time monitoring and control algorithm supports autonomous defect detection and compensation. Such techniques may improves reproducibility and yield, for example, increasing the percentage of printed films with high electrical conductivity from 44 percent to 94 percent.

Co-jet printing techniques described herein may also deliver electrical conductivity in printed silver films comparable to thermal sintering performed outside the printing step. Such processes may maintain temperatures near ambient conditions and may shorten overall manufacturing time by eliminating additional post-printing treatments.

Experimental validations described here show that the co-jet printing techniques may facilitate direct fabrication of hydration sensors on living plant leaves. These sensors may be operable to track hydration level changes in plants over extended durations. Concurrent deposition and sintering streamline the fabrication process and expand the range of temperature-sensitive materials suitable for functional device printing.

The versatility of co-jet printing techniques further creates opportunities for integrating abiotic and biotic materials. Potential applications include wearable devices, implantable systems, and biohybrid platforms.

In some aspects, the techniques described herein relate to a coaxial nozzle assembly, including: a nozzle body defining a longitudinal axis; a central conduit extending through the nozzle body along the longitudinal axis, the central conduit having a first inlet and a first outlet; a first outer annular flow channel extending through the nozzle body, the first outer annular flow channel concentrically surrounding the central conduit about the longitudinal axis, the first outer annular flow channel being radially outward from the longitudinal axis relative to the central conduit, the first outer annular flow channel having a second inlet and a second outlet; a first electrode positioned radially opposed to a second electrode with respect to the longitudinal axis, the first electrode and the second electrode being positioned proximate the second outlet, a portion of the nozzle body being positioned between the first electrode and the outer annular flow channel, the portion of the nozzle body including a dielectric material; an aerosol generator body positioned upstream of the nozzle body, the aerosol generator body having a third inlet and a third outlet, the third inlet and the third outlet being aligned with the longitudinal axis, the third outlet being fluidly coupled to the first inlet; a first chamber formed in the aerosol generator body, the first chamber having a radius greater than a radius of the third inlet and a radius of the third outlet with respect to the longitudinal axis; and a second outer annular flow channel extending through the aerosol generator body, the second outer annular flow channel concentrically surrounding the first chamber about the longitudinal axis, the second outer annular flow channel being radially outward from the longitudinal axis relative to the first chamber, the second outer annular flow channel having a fourth inlet and a fourth outlet.

In some aspects, the techniques described herein relate to a coaxial nozzle assembly, wherein the second inlet has a radius greater than a radius of the second outlet, such that the first outer annular flow channel defines a first radially converging flow path toward the longitudinal axis.

In some aspects, the techniques described herein relate to a coaxial nozzle assembly, wherein the fourth inlet has a radius greater than a radius of the fourth outlet, such that the second outer annular flow channel defines a second radially converging flow path toward the longitudinal axis.

In some aspects, the techniques described herein relate to a coaxial nozzle assembly, further including a converging section formed in the aerosol generator body, the converging section being positioned between and fluidly coupling (i) the first chamber and the third outlet and (ii) the fourth outlet and the third outlet.

In some aspects, the techniques described herein relate to a coaxial nozzle assembly, wherein the converging section defines an interior surface of the aerosol generator body tapering inward toward the longitudinal axis.

In some aspects, the techniques described herein relate to a coaxial nozzle assembly, further including an atomizer in operative communication with the aerosol chamber.

In some aspects, the techniques described herein relate to a coaxial nozzle assembly, wherein: the third inlet and the first chamber define a first fluid path for a carrier gas flow; the fourth inlet, second outer annular flow channel, and fourth outlet define a second fluid path for a sheath gas flow that concentrically surrounds and aerodynamically focus the carrier gas flow at the converging section to form an aerosol ink stream. the fourth outlet, central conduit, and the first outlet define a third fluid path for the aerosol ink stream; the second inlet, first outer annular flow channel, and second outlet define a fourth fluid path for a plasma working gas flow that is ionized by an electric potential applied across the first electrode and the second electrode to transition the plasma working gas flow into a near-ambient temperature plasma stream, the plasma stream substantially coaxially surrounding the aerosol ink stream as the aerosol ink stream exits the first outlet.

In some aspects, the techniques described herein relate to a method of forming and delivering an aerosol stream, including: providing a carrier gas flow including atomized nanoparticles to a first inlet of an aerosol generator body, wherein the carrier gas flows from the first inlet to a first chamber formed in the aerosol generator body and expands within the first chamber; providing a sheath gas flow to a second inlet of a first outer annular flow channel formed in the aerosol generator body, the first outer annular flow channel concentrically surrounding the first chamber, wherein the sheath gas flow is directed from a second outlet of the first outer annular flow channel to aerodynamically focus the expanded carrier gas flow and form a confined aerosol ink stream within a converging section positioned between the first chamber and a first outlet of the aerosol generator body; delivering the aerosol ink stream from the first outlet of the aerosol generator body to a third inlet of a central conduit extending through a nozzle body, the aerosol ink stream exiting the nozzle body through a third outlet of the central conduit; providing a plasma working gas flow to a fourth inlet of a second outer annular flow channel formed in the nozzle body, the second outer annular flow channel concentrically surrounding the central conduit; applying an electric potential across a first electrode and a second electrode positioned proximate a fourth outlet of the second outer annular flow channel to ionize the plasma working gas flow and form a near-ambient temperature plasma stream, the plasma stream exiting the fourth outlet and substantially coaxially surrounding the aerosol ink stream.

In some aspects, the techniques described herein relate to a method, further including positioning the nozzle body to direct the aerosol ink stream and the plasma stream toward a substrate to facilitate sintering of nanoparticles of the aerosol ink stream upon deposition at the substrate.

In some aspects, the techniques described herein relate to a method, wherein the electric potential is a pulsed voltage generated using a voltage pulse generator, the pulsed voltage exceeding a breakdown threshold of the plasma working gas.

In some aspects, the techniques described herein relate to a method, further including generating, at an atomizer positioned in operative communication with the first chamber, ultrasonic waves that induce pressure fluctuations in the expanded carrier gas flow.

In some aspects, the techniques described herein relate to a method, wherein the carrier gas flow includes an inert gas transporting atomized nanoparticles from an upstream aerosolization source to the first inlet.

In some aspects, the techniques described herein relate to a method, wherein the atomized nanoparticles include metal nanoparticles, metal oxide nanoparticles, semiconductor nanoparticles, quantum dot nanoparticles, dielectric nanoparticles, carbon-based nanoparticles, biologically active nanoparticles, polymeric nanoparticles, or a combination thereof.

In some aspects, the techniques described herein relate to a method, wherein the plasma working gas flow includes a substantially inert gas that forms a plurality of plasma streamers when ionized by the electric potential.

In some aspects, the techniques described herein relate to a system, including: non-transitory computer-readable storage media storing instructions; and an electronic processor configured to execute the instructions to: receive, from a live inspection camera, an image frame capturing deposition of an aerosol ink stream onto a substrate, the aerosol ink stream being coaxially surrounded by a plasma stream, the plasma stream being at a near-ambient temperature, segment the image frame to define a plasma jet region, the plasma jet region corresponding to a portion of the image frame including the plasma stream, provide the image frame to a machine learning model to generate a pixel-level anomaly heatmap including a plurality of pixel values, each pixel value being indicative of a likelihood of an anomaly at a corresponding location in the image frame, determine a plasma jet region anomaly score based on pixel values of the anomaly heatmap within the plasma jet region, in response to determining that the plasma jet region anomaly score exceeds a first threshold, reduce a voltage applied to electrodes of a coaxial nozzle assembly configured to generate the plasma stream, and in response to determining that the plasma jet region anomaly score does not exceed the first threshold, increase the voltage applied to the electrodes.

In some aspects, the techniques described herein relate to a system, wherein the electronic processor is further configured to execute the instructions to: segment the image frame to define a printed film region, the printed film region corresponding to a portion of the image frame representing a deposited film on the substrate; determine a printed film region anomaly score based on pixel values of the anomaly heatmap within the printed film region; and in response to determining that the printed film region anomaly score exceeds a second threshold, mark the image frame as anomalous.

In some aspects, the techniques described herein relate to a system, wherein the electronic processor is further configured to execute the instructions to: compute an anomaly ratio based on a ratio of image frames marked as anomalous to a total number of image frames captured during a printing pass; and in response to determining that the anomaly ratio exceeds a third threshold, initiate a repair action.

In some aspects, the techniques described herein relate to a system, wherein the electronic processor is further configured to execute the instructions to initiate the repair action by: printing a first new layer on the substrate with the plasma stream disabled by withholding voltage from the electrodes; and printing a second new layer over the first new layer with the plasma stream enabled by applying a pulsed voltage to the first electrode and the second electrode that exceeds a breakdown threshold of a plasma working gas.

In some aspects, the techniques described herein relate to a system, wherein the machine learning model is trained using a training dataset consisting of unlabeled image frames representing non-anomalous conditions.

In some aspects, the techniques described herein relate to a system, wherein the machine learning model includes: a convolutional neural network configured to extract feature vectors from the image frame, the feature vectors representing a collection of local patches from the image frame; a memory bank storing a subset of feature vectors representing nominal patches from the training dataset; and nearest-neighbor comparison logic configured to compute, for each test patch, an anomaly score based on a distance between the feature vector for the test patch and a nearest feature vector in the memory bank.

Other examples, embodiments, features, and aspects will become apparent by consideration of the detailed description and accompanying drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a block diagram illustrating an example co-jet printing system, according to some examples.

FIG. 2A is a cross-sectional view of an exemplary embodiment of the nozzle assembly of FIG. 1.

FIG. 2B is a detailed view, taken at reference FIG. 2B in FIG. 2A, illustrating features of the example nozzle assembly of FIG. 2A and an example plasma jet generation process.

FIG. 3 is a block diagram illustrating data flow between components of an example of the machine learning model of FIG. 1.

FIG. 4 is a schematic illustration of an example image frame.

FIG. 5 is a flowchart illustrating an example process for automatically controlling a voltage supplied to a nozzle assembly.

FIG. 6 is a flowchart illustrating an example process for automatically controlling printing passes.

FIG. 7 illustrates an example experimental characterization of plasma jet characteristics.

FIG. 8 provides example photographs demonstrating co-jet printing of silver nanoparticle ink.

FIG. 9 illustrates additional example implementations of co-jet printing.

FIG. 10 illustrates example characterizations of a co-jet printing system.

FIG. 11 illustrates example Schlieren imaging characterizations of combined gas flows exiting a nozzle assembly.

FIG. 12 illustrates example microscope images of silver nanoparticle films printed under different carrier gas flow conditions.

FIG. 13 illustrates example manufacturing time comparisons between co-jet printing and conventional processes.

FIG. 14 illustrates example implementations of in situ defect detection and compensation integrated with a co-jet printing process.

FIG. 15 illustrates a distribution of example samples printed with randomly generated printing parameters with their online detection and compensation results.

FIG. 16 illustrates example implementations of co-jet printing on biological materials.

FIG. 17 illustrates an example line pattern printed using the co-jet printing process.

FIG. 18 illustrates a schematic of an example infrared measurement arrangement.

FIG. 19 is a schematic illustration of an example in-situ inspection setup.

In the drawings, reference numbers may be reused to identify similar and/or identical elements.

### DETAILED DESCRIPTION

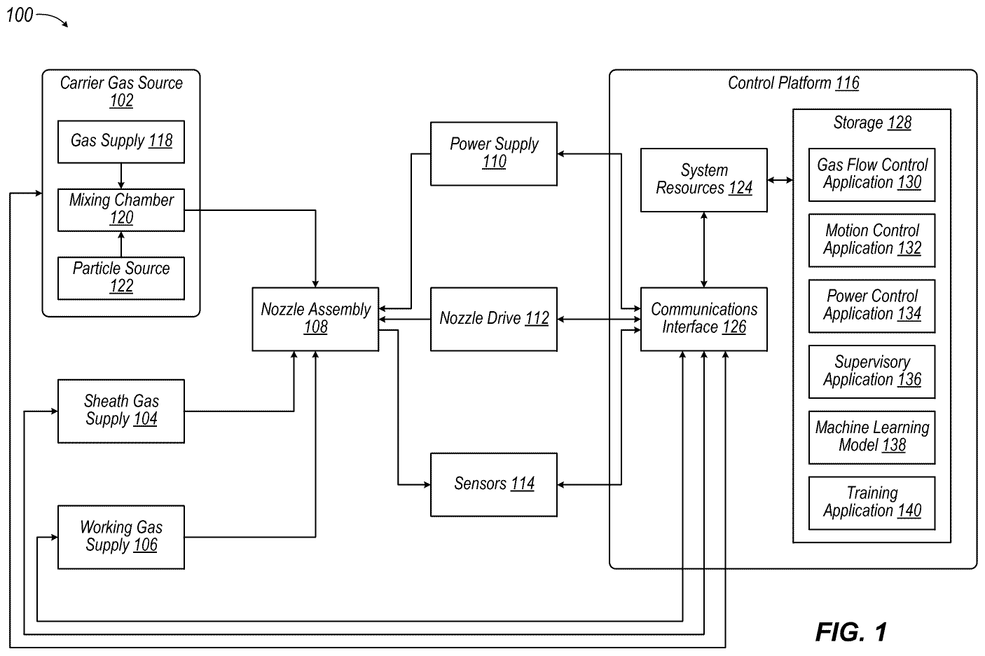

FIG. 1 is a block diagram illustrating an example co-jet printing system 100. In various implementations, the system 100 includes a carrier gas source 102, a sheath gas supply 104, a working gas supply 106, a nozzle assembly 108, a power supply 110, a nozzle drive 112, sensors 114, and a control platform 116. The carrier gas source 102 may supply a carrier gas including aerosolized particles—for example, in particles or nanoparticles—toward the nozzle assembly 108. In some examples, the carrier gas source 102 includes a gas supply 118, a mixing chamber 120, and a particle source 122.

In various implementations, the carrier gas includes an inert gas, such as argon, helium, nitrogen, or a mixture thereof, delivered from the gas supply 118. The gas supply 118 may further include flow metering hardware, for example, a mass flow controller, flow sensor, or flow regulator configured to establish and maintain a desired carrier gas flow rate. The particle source 122 may introduce particles such as, for example, metal nanoparticles, metal oxide nanoparticles, semiconductor nanoparticles, quantum dot nanoparticles, dielectric nanoparticles, carbon-based nanoparticles, biologically active nanoparticles, polymeric nanoparticles, or combinations thereof.

In various implementations, the particle source 122 may also introduce ink, such as liquids or suspensions containing particles or nanoparticles. For example, the ink may include metal particle or nanoparticle inks (such as aqueous silver nanoparticle inks comprising silver nanoparticles dispersed in water with a cosolvent like ethylene glycol and optional additives such as defoamers or surfactants), metal oxide particle or nanoparticle inks, semiconductor particle or nanoparticle inks, carbon-based particle or nanoparticle inks, polymeric particle or nanoparticle inks, biologically active inks, or other suitable inks. Such inks may further contain dissolved or dispersed non-particulate constituents including solvents, cosolvents, binders, surfactants, and other processing additives.

In some examples, the particle source 122 may also incorporate flow metering hardware to regulate particle entrainment into the carrier gas. The flow metering hardware may be controllable by the control platform 116. The gas supply 118 and the particle source 122 may each be fluidly coupled to the mixing chamber 120.

In some examples, the mixing chamber 120 provides an expansion region where the carrier gas and particles undergo dispersion or mixing to form an aerosol flow. In various implementations, the mixing chamber 120 may include a plenum, a manifold, or another suitable chamber configured to promote uniform mixing. The aerosol flow may comprise droplets with entrained nanoparticles, for example, droplets formed by ultrasonic atomization or other aerosolization processes. The mixing chamber 120 may be fluidly coupled to the nozzle assembly 108 such that the aerosol flow is delivered downstream for further processing.

In various implementations, the sheath gas supply 104 provides a sheath gas flow directed to the nozzle assembly 108. The sheath gas supply 104 may include flow metering hardware, for example, a mass flow controller, flow sensor, or flow regulator configured to establish and maintain a desired sheath gas flow rate. The flow metering hardware may be controllable by the control platform 116. The sheath gas may include helium, argon, nitrogen, or mixtures thereof. The sheath gas supply 104 may be fluidly coupled to the nozzle assembly 108 such that the sheath gas aerodynamically interacts with the aerosol flow to support stream confinement.

In some examples, the working gas supply 106 may provide a working gas flow directed to the nozzle assembly 108. The working gas supply 106 may include flow metering hardware, for example, a mass flow controller, flow sensor, or flow regulator configured to establish and maintain a desired working gas flow rate. The flow metering hardware may be controllable by the control platform 116. The working gas may include helium, argon, nitrogen, or mixtures thereof. The working gas supply 106 may be fluidly coupled to the nozzle assembly 108 such that the working gas flow supports plasma jet generation and propagation.

In various implementations, the power supply 110 provides electrical energy to the nozzle assembly 108. The power supply 110 may include circuitry configured to generate and apply an electrical potential across electrodes positioned proximate to outlets of the nozzle assembly 108. The power supply 110 may be operatively connected to the electrodes such that an applied potential ionizes a working gas flow to generate a plasma jet. The power supply 110 may be controlled by the control platform 116.

In some examples, the power supply 110 includes a high-voltage pulse generator biased by a direct current power supply and configured to deliver pulsed electrical potentials exceeding a breakdown threshold of the working gas. The pulsed potentials may be applied in the form of direct current or alternating current waveforms. The applied potential may be adjustable in magnitude, frequency, or duty cycle to establish a stable plasma jet.

In some examples, the power supply 110 further includes ballast resistance, impedance-matching circuitry, or other current-limiting elements to stabilize the discharge. The power supply 110 may also incorporate monitoring components, for example, voltage or current measurement circuitry suitable for diagnostic purposes. In various implementations, the power supply 110 may deliver pulses of positive or negative polarity to control plasma discharge characteristics.

In various implementations, the nozzle drive 112 may provide mechanical positioning of the nozzle assembly 108. The nozzle drive 112 may support translation, rotation, or other controlled motion of the nozzle assembly 108 relative to a substrate. Such motion may facilitate alignment, scanning, or patterning during co-jet printing operations. The nozzle drive 112 may be mechanically coupled to the nozzle assembly 108 and may be controlled by the control platform 116.

In some examples, the nozzle drive 112 may include linear actuators, rotary actuators, or stepper motors configured to provide controlled displacement. In other implementations, the nozzle drive 112 may include precision positioning hardware such as piezoelectric stages, servo-driven translation stages, or robotic arms. The nozzle drive 112 may further include mounting structures, rails, or brackets to support rigid coupling to the nozzle assembly 108. In various implementations, the nozzle drive 112 may provide single-axis or multi-axis movement, and may be configured for incremental stepwise motion or continuous scanning.

In various implementations, the sensors 114 may monitor operational conditions of the nozzle assembly 108. The sensors 114 may generate signals indicative of physical, electrical, thermal, or flow characteristics associated with the nozzle assembly 108. The sensors 114 may provide sensor signals to the control platform 116 and may be controlled by the control platform 116.

In some examples, the sensors 114 may include optical sensors, such as cameras, imaging systems, or photodetectors, configured to capture images of the plasma jet, aerosol flow, or deposited material. In other implementations, the sensors 114 may include thermal sensors, such as infrared cameras, infrared detectors, thermocouples, or pyrometers, configured to monitor temperature near the nozzle assembly 108 or at a substrate. In various implementations, the sensors 114 may include electrical sensors, such as voltage probes or current sensors, to monitor discharge conditions of the power supply 110. The sensors 114 may also include flow sensors, such as pressure transducers or mass flow sensors, to monitor carrier, sheath, or working gas flow conditions. In some examples, the sensors 114 may include acoustic, vibration, or position sensors to track mechanical stability of the nozzle assembly 108 during operation.

In various implementations, the nozzle assembly 108 may receive multiple inputs and deliver a combined output for co-jet printing. The nozzle assembly 108 may receive a carrier gas flow including entrained particles from the carrier gas source 102, a sheath gas flow from the sheath gas supply 104, a working gas flow from the working gas supply 106, and an electrical supply from the power supply 110. The nozzle assembly 108 may be positioned by the nozzle drive 112 relative to a substrate.

During operation, the nozzle assembly 108 may direct the carrier gas flow toward the substrate for material deposition. The sheath gas flow may concentrate and focus the carrier gas flow into a confined aerosol jet. The working gas flow, when energized by the electrical supply from the power supply 110, may form a plasma jet that interacts with the aerosol stream near the substrate. The combined action may deposit particles onto the substrate surface while promoting in situ sintering of the deposited nanoparticles at or near ambient temperature.

In various implementations, the control platform 116 includes system resources 124, a communications interface 126, and non-transitory computer-readable storage media, such as storage 128. The system resources 124 may include one or more electronic processors, graphics processing units, volatile and non-volatile computer memory, and system buses interconnecting components of the control platform 116. The non-transitory computer-readable storage media may store instructions that, when executed, cause one or more electronic processors of the system resources 124 to perform functions described herein. The communications interface 126 may include one or more transmitters, receivers, or transceivers configured to exchange data with other components of the system 100.

In some examples, the communications interface 126 may support wired or wireless communications protocols for interaction with system components. Suitable protocols may include serial interfaces, such as RS-232 or RS-485; digital communication buses, such as I2C, SPI, or CAN bus; and industrial communication standards, such as EtherCAT, Modbus, or Profibus. In various implementations, the communications interface 126 may support Ethernet-based protocols, wireless local area protocols such as Wi-Fi, or short-range protocols such as Bluetooth. The communications interface 126 may be configured to exchange sensor data with the sensors 114, transmit control signals to the power supply 110, the nozzle drive 112, the gas supply 118, the particle source 122, the sheath gas supply 104, or the working gas supply 106, and receive monitoring data or diagnostics from those components.

In various implementations, the storage 128 includes a gas flow control application 130, a motion control application 132, a power control application 134, a supervisory application 136, a machine learning model 138, and a training application 140. The gas flow control application 130 may generate commands for the gas supply 118, the particle source 122, the sheath gas supply 104, or the working gas supply 106 to adjust carrier, sheath, or working gas flow rates. The motion control application 132 may generate commands for the nozzle drive 112 to position the nozzle assembly 108 relative to a substrate. The power control application 134 may generate commands for the power supply 110 to adjust applied voltage, frequency, or duty cycle.

In various implementations, the supervisory application 136 may monitor signals received from the sensors 114 and may process such signals to perform anomaly detection using the machine learning model 138. The supervisory application 136 may transmit control signals to the gas flow control application 130, the motion control application 132, and the power control application 134 based on the monitoring and anomaly detection. The machine learning model 138 may be trained to analyze sensor signals, for example, camera images of a plasma jet or printed film, to identify deviations from expected conditions. In some examples, the training application 140 may provide iterative updates to the machine learning model 138 using stored sensor data, unlabeled data, annotated data, or other training inputs to improve performance over time.

In various implementations, the machine learning model 138 includes one or more model classes suitable for anomaly detection from sensor data. Suitable classes include unsupervised anomaly detection models, one-class classification models, self-supervised representation learning models, and reconstruction-based models. Examples include a convolutional neural network feature extractor with a memory bank and a nearest-neighbor anomaly scorer, a vision transformer feature extractor with a memory bank, a convolutional autoencoder or variational autoencoder with reconstruction-error scoring, a one-class support vector machine operating on learned feature vectors, an isolation forest operating on learned feature vectors, a Gaussian mixture model density estimator, or a hybrid that combines a feature extractor with a distance- or density-based scorer. In some examples, the machine learning model 138 generates a pixel-level anomaly heatmap for frames acquired by cameras of the sensors 114, with region-level scores computed over a plasma jet region and a printed film region.

In various implementations, the machine learning model 138 includes a PatchCore anomaly detection architecture. The PatchCore implementation may include a convolutional neural network (CNN) configured to extract feature vectors representing a collection of local patches from an input image frame, a memory bank storing representative feature vectors from nominal patches, and nearest-neighbor comparison logic that assigns an anomaly score to each test patch based on distance to stored nominal features. The machine learning model 138 may be trained using image frames that represent non-anomalous conditions, such that stored features in the memory bank correspond to nominal operation without defects or plasma irregularities. During training, the machine learning model 138 may receive unannotated or unlabeled image frames collected during nominal operation, may extract patch-level features, and may populate the memory bank with a subset of nominal features. In some examples, a reconstruction-based model within the machine learning model 138 may be optimized to minimize reconstruction error on nominal frames, and a one-class model may be fitted to feature embeddings derived from nominal frames, establishing a decision region that characterizes nominal operation.

Additional functionality of the gas flow control application 130, motion control application 132, power control application 134, supervisory application 136, machine learning model 138, and training application 140 is described herein.

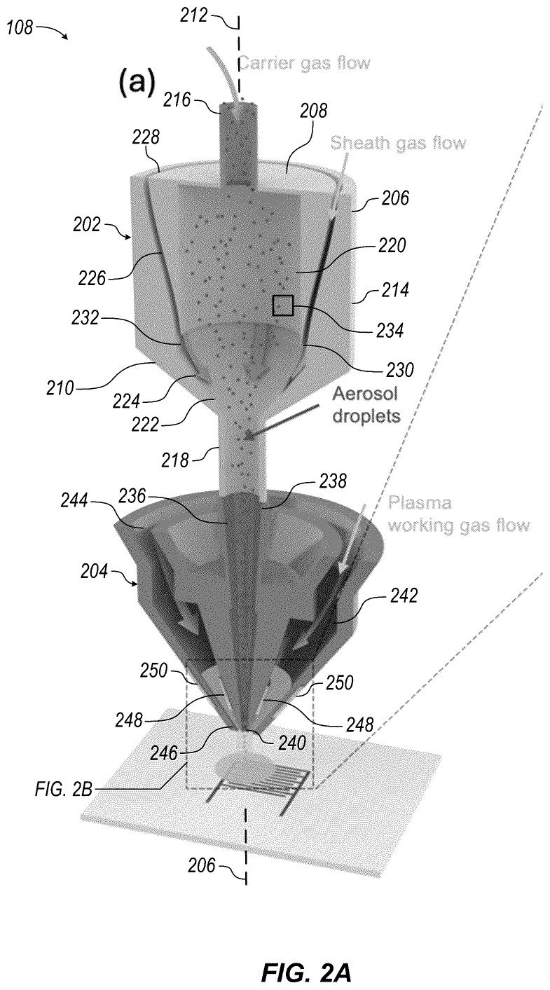

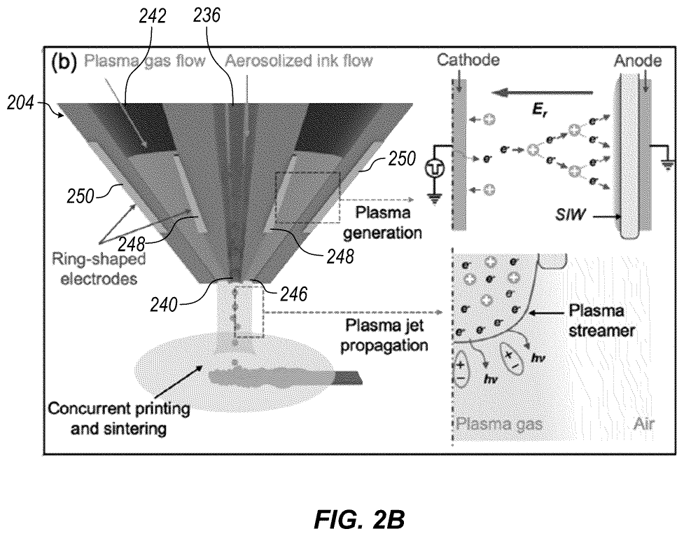

FIG. 2A is a cross-sectional view of an example of the nozzle assembly 108 of FIG. 1. In various implementations, the nozzle assembly 108 includes an aerosol generator body 202 and a nozzle body 204. In the example of FIG. 2A, the aerosol generator body 202 includes a substantially conical body portion 206, a substantially planar exterior face 208, and a truncated substantially conical body portion 210 at an opposite end of the aerosol generator body 202. The aerosol generator body 202 may be substantially symmetrical about a longitudinal axis 212 such that an exterior sidewall 214 of the conical body portion 206 is substantially parallel to the axis 212 while the exterior face 208 is substantially orthogonal to the axis 212. In other implementations, the aerosol generator body 202 includes alternative geometries.

In some examples, the aerosol generator body 202 includes an inlet 216 positioned at a first end, such as at the exterior face 208, and an outlet 218 positioned at a second end opposite the first end. A chamber 220 may be disposed within the aerosol generator body 202, for example as a substantially conical cavity formed within the conical body portion 210. The chamber 220 may be fluidly coupled to a converging section 222. The inlet 216 and the outlet 218 may be fluidly coupled via the chamber 220 and the converging section 222. The inlet 216 may include an interior radius, measured substantially orthogonal to the axis 212, that is less than an interior radius of the chamber 220 measured substantially orthogonal to the axis 212. An end of the converging section 222 adjacent to the chamber 220 may include an interior radius substantially equal to the interior radius of the chamber 220. An end of the converging section 222 adjacent to the outlet 218 may include an interior radius less than the interior radius of the chamber 220, such that an interior surface 224 of the converging section 222 defines a converging surface extending from the chamber 220 toward the outlet 218 with the converging surface decreasing in radius with decreasing axial distance toward the outlet 218. In some implementations, the converging surface may be a truncated substantially conical surface.

In various implementations, the chamber 220 may include an atomizer 234 configured to generate an aerosol flow from a carrier gas and suspended particles. Suitable examples of the atomizer 234 include an ultrasonic atomizer, a pneumatic atomizer, a piezoelectric atomizer, an electrospray atomizer, or a nebulizer-based atomizer. The atomizer 234 may be operatively coupled to the chamber 220 such that the generated aerosol is introduced directly into the chamber 220. The atomizer 234 may be in communication with the communications interface 126 and may be controlled by the gas flow control application 130 to regulate atomization parameters such as excitation frequency, applied voltage, gas entrainment rate, or droplet size distribution.

In various implementations, an outer annular flow channel 226 is formed concentrically around the chamber 220 within the aerosol generator body 202. The outer annular flow channel 226 may include an inlet 228 positioned at the exterior face 208 and an outlet 230 opening into an intermediate region 232 between the chamber 220 and the converging section 222. The outer annular flow channel 226 may be substantially symmetrical about the axis 212 and may taper such that inner and outer radiuses of the outer annular flow channel 226, as measured substantially orthogonal to the axis 212, are greater at the inlet 228 than at the outlet 230.

In various implementations, the nozzle body 204 includes a truncated substantially conical structure that is substantially symmetric about the axis 212. In other examples, the nozzle body 204 may include an alternative geometry. The nozzle body 204 may further include a central conduit 236 extending through the nozzle body 204 along the axis 212. The central conduit 236 may include an inlet 238 positioned at a first end and an outlet 240 positioned at an opposite end. The nozzle body 204 may additionally include an outer annular flow channel 242 formed concentrically through the nozzle body 204 surrounding the central conduit 236. The outer annular flow channel 242 may be substantially symmetric about the axis 212 and may include an inlet 244 positioned proximate to the inlet 238 and an outlet 246 positioned proximate to the outlet 240. In some examples, the outer annular flow channel 242 may taper toward the outlet 240 such that inner and outer radiuses of the inlet 244, as measured substantially orthogonal to the axis 212, are greater than respective inner and outer radiuses of the outlet 246.

In various implementations, the nozzle body 204 includes one or more electrodes positioned proximate to the outlet 240. Suitable examples include ring electrodes, plate electrodes, pin electrodes, or mesh electrodes. In the example illustrated in FIG. 2A, the electrodes include a pair of ring electrodes, identified as electrode 248 and electrode 250. In some implementations, one of the electrodes 248 or 250 is in direct contact with an interior volume of the outer annular flow channel 242, while the other electrode is separated from the interior volume by a dielectric material. For example, a portion of the nozzle body 204 may be formed from a dielectric material such that the dielectric material covers the outer electrode 250 with respect to the interior volume. In other implementations, neither electrode is covered by a dielectric material, or both electrodes are covered by dielectric material. Alternative configurations may include embedded electrodes within walls of the nozzle body 204, segmented electrodes distributed circumferentially around the outlet 240, or electrodes arranged in offset or staggered orientations relative to the axis 212.

In various implementations, the aerosol generator body 202 and the nozzle body 204 may be fabricated as discrete structures. The outlet 218 of the aerosol generator body 202 may be fluidly connected to the inlet 238 of the nozzle body 204 such that the aerosol flow transitions from the chamber 220 and the converging section 222 into the central conduit 236. The aerosol generator body 202 and the nozzle body 204 may be joined by a mechanical coupling, adhesive bonding, threaded connection, or interference fit. In some examples, the joining region may further incorporate a gasket or sealing element configured to reduce leakage between the outlet 218 and the inlet 238.

In other implementations, the aerosol generator body 202 and the nozzle body 204 may be formed as a single integrated structure. In such examples, the outlet 218 may transition directly into the inlet 238 without a discrete joining region. The integrated structure may simplify assembly, reduce potential misalignment, and improve flow uniformity through the nozzle assembly 108.

In various implementations, the aerosol generator body 202 and the nozzle body 204 may be fabricated from materials suitable for structural stability, dielectric isolation, or thermal resistance. Examples of suitable materials include ceramics such as alumina, zirconia, or silicon nitride; polymers such as polytetrafluoroethylene (PTFE), polyether ether ketone (PEEK), or high-performance thermosetting resins; and composite materials combining ceramic or polymeric phases.

In some examples, the aerosol generator body 202 and the nozzle body 204 may be produced using conventional or additive manufacturing processes. Suitable processes include machining, milling, or turning of metallic stock; injection molding or compression molding of polymeric materials; ceramic casting or sintering; or additive manufacturing techniques such as stereolithography, selective laser sintering, fused deposition modeling, or direct metal laser sintering. In various implementations, post-processing steps such as polishing, coating, or surface treatment may be applied to achieve desired dimensional tolerances, smooth interior surfaces, or enhanced wear resistance.

In various implementations, the carrier gas source 102 is fluidly coupled to the chamber 220 of the aerosol generator body 202. The gas supply 118 may provide a carrier gas, such as helium, argon, nitrogen, or mixtures thereof, through flow metering hardware configured to regulate flow rate. The particle source 122 may introduce particles (such as, for example, inks containing particles or nanoparticles) into the carrier gas, for example through entrainment or another suitable delivery mechanism, to form a particle-laden carrier gas stream. In some examples, the atomizer 234 disposed within the chamber 220 may impart energy to the carrier gas stream to disperse and suspend particles, such as nanoparticles, polymers, or biologically active materials, into a uniform aerosol. The aerosol stream may expand within the chamber 220, where flow velocity decreases and particles undergo initial spatial distribution. The aerosol stream may then be directed toward the converging section 222, where the flow geometry narrows and accelerates the aerosol stream, reducing dispersion and shaping the flow as it exits through the outlet 218. The outlet 218 may be fluidly coupled to the inlet 238 of the central conduit 236 such that the aerosol stream transitions directly into the nozzle body 204.

In some examples, the sheath gas supply 104 is fluidly coupled to the outer annular flow channel 226 of the aerosol generator body 202. The sheath gas supply 104 may provide a sheath gas, such as helium, argon, nitrogen, or mixtures thereof, through flow metering hardware configured to regulate flow rate. The sheath gas may enter the inlet 228 of the outer annular flow channel 226 and flow concentrically around the chamber 220 toward the outlet 230. At the outlet 230, the sheath gas may merge with the aerosol stream in the intermediate region 232 between the chamber 220 and the converging section 222. The sheath gas may form an annular layer surrounding the aerosol stream, stabilizing the flow, reducing boundary layer turbulence, and supporting acrodynamic focusing of the aerosol stream as it progresses through the converging section 222 and into the central conduit 236.

In various implementations, the working gas supply 106 is fluidly coupled to the outer annular flow channel 242 of the nozzle body 204. The working gas supply 106 may provide a working gas, such as helium, argon, nitrogen, or mixtures thereof, through flow metering hardware configured to regulate flow rate. The working gas may enter the inlet 244 of the outer annular flow channel 242 and flow concentrically along the central conduit 236. The outer annular flow channel 242 may taper toward the outlet 246, accelerating the working gas and directing it toward the outlet 240 of the central conduit 236. At the outlet 240, the working gas may emerge concentrically around the aerosol stream, providing a controlled flow region in which sintering occurs.

In some examples, the power supply 110 is operatively coupled to the electrodes 248 and 250 positioned proximate to the outlet 240 of the nozzle body 204. The power supply 110 may deliver a pulsed or continuous electrical potential across the electrodes 248 and 250. The applied potential may ionize the working gas as it flows through the gap between the electrodes 248 and 250, generating a plasma jet that exits the outlet 246 extends downstream of the nozzle assembly 108. The plasma jet may propagate coaxially with the aerosol stream and may contain reactive plasma species and photons. These plasma constituents may interact with the aerosol stream and with deposited material at the substrate surface, promoting in situ sintering or other processing of the deposited particles.

In various implementations, the nozzle drive 112 is mechanically coupled to the nozzle assembly 108 to provide controlled motion relative to a substrate. The nozzle drive 112 may include actuators, translation stages, or robotic arms connected to mounting brackets, clamps, or rails that secure the nozzle assembly 108. The nozzle drive 112 may support translation along one or more axes, rotation, or scanning motions. Through such coupling, the nozzle drive 112 may position the nozzle assembly 108 so that the combined aerosol stream and plasma jet are directed to predetermined substrate regions during operation.

During coordinated operation, the gas flow control application 130 of the control platform 116 may transmit commands to the flow metering hardware of the carrier gas source 102, the sheath gas supply 104, and the working gas supply 106, regulating respective flow rates. The gas flow control application 130 may also transmit control signals to the atomizer 234 to adjust atomization parameters. The power control application 134 may transmit commands to the power supply 110 to adjust applied voltage magnitude, frequency, or duty cycle, thereby generating stable plasmas at the electrodes 248 and 250. The motion control application 132 may transmit commands to the nozzle drive 112 to position the nozzle assembly 108 with respect to the substrate.

In operation, the carrier gas flow containing suspended particles (for example, inks containing particles or nanoparticles) may be directed through the central conduit 236 and discharged through the outlet 240 toward the substrate. The sheath gas flow may emerge concentrically from the outlet 230 and aerodynamically focus the carrier gas flow into a confined aerosol stream. The working gas flow may emerge from the outlet 246 and be ionized by the applied potential at the electrodes 248 and 250, forming a plasma jet that propagates coaxially with the aerosol stream. At the substrate surface, the combined effect may deposit particles with spatial precision while simultaneously exposing the deposited particles to reactive plasma constituents, thereby supporting in situ sintering or surface modification at or near ambient temperature.

FIG. 2B is a detailed view, taken at reference FIG. 2B in FIG. 2A, illustrating features of the example nozzle assembly 108 of FIG. 2A. In various implementations, an annular plasma jet propagates coaxially with an aerosol ink flow through an outer path of the deposition nozzle. The plasma is generated between two ring-shaped electrodes 248 and 250 and continues to propagate downstream of the nozzle.

In some examples, the aerosol is aerodynamically focused into a narrow aerosol jet by a sheath gas flow provided from the sheath gas supply 104, supporting high spatial resolution deposition on a substrate. A second component associated with plasma generation may take the form of an annular pulsed dielectric barrier discharge plasma jet, with a plasma working gas flowing coaxially to the aerosol stream through the outer annular path of the nozzle assembly 108. In the example of FIG. 2B, a cathode electrode 248 is mounted on an inner nozzle wall and a grounded anode electrode 250 is mounted on an outer nozzle wall.

The inserts of FIG. 2B illustrate example processes of plasma jet formation and propagation. As plasma is generated between the electrodes 248 and 250, the induced surface ionization waves (SIWs) may propagate along interior walls of the nozzle body 204 and emerge from the outlet 246 of the nozzle body 204, where the plasma jet discharge may interact with the aerosol jet. In various implementations, the plasma interacts with aerosol particles both in transit and at the point of impact on the substrate, promoting nanoparticle sintering concurrent with deposition.

The use of an atmospheric pressure plasma jet operating near ambient temperature provides compatibility with delicate or temperature-sensitive substrates. In some examples, the coaxial configuration of FIG. 2B also decouples the aerosol flow path from the plasma flow path, supporting independent tuning of carrier gas, sheath gas, and working gas conditions for different substrates, ink formulations, or device structures.

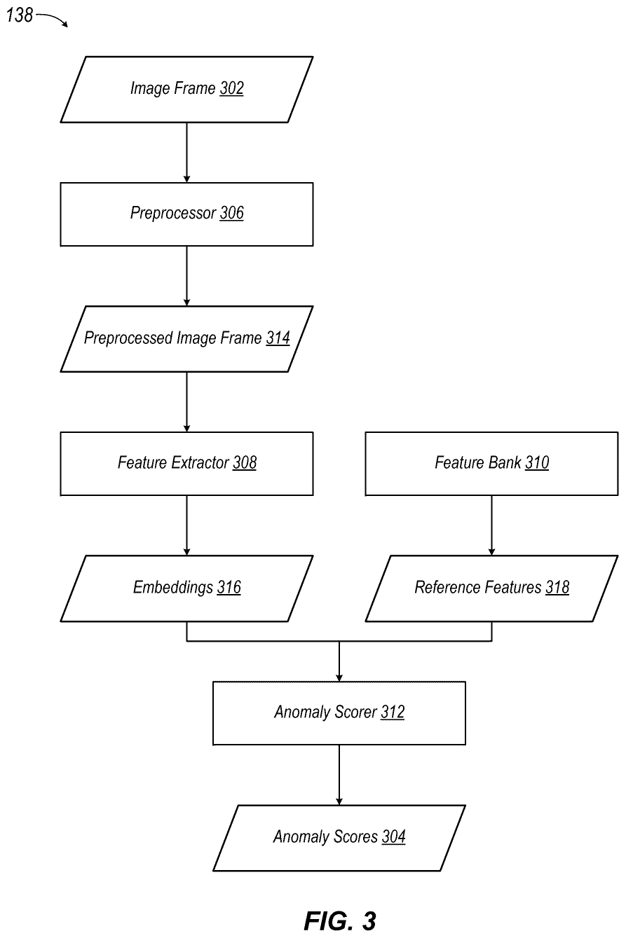

FIG. 3 is a block diagram illustrating example data flow between components of an example of the machine learning model 138 of FIG. 1. In various implementations, the machine learning model 138 is configured to receive an image frame 302 and output anomaly scores 304. For example, the machine learning model 138 may include a preprocessor 306, a feature extractor 308, a feature bank 310, and an anomaly scorer 312. The preprocessor 306 may receive an image frame 302 as input. In some examples, the supervisory application 136 may generate the image frame 302 by processing sensor signals acquired from the sensors 114, which may capture the nozzle assembly 108 during a printing process.

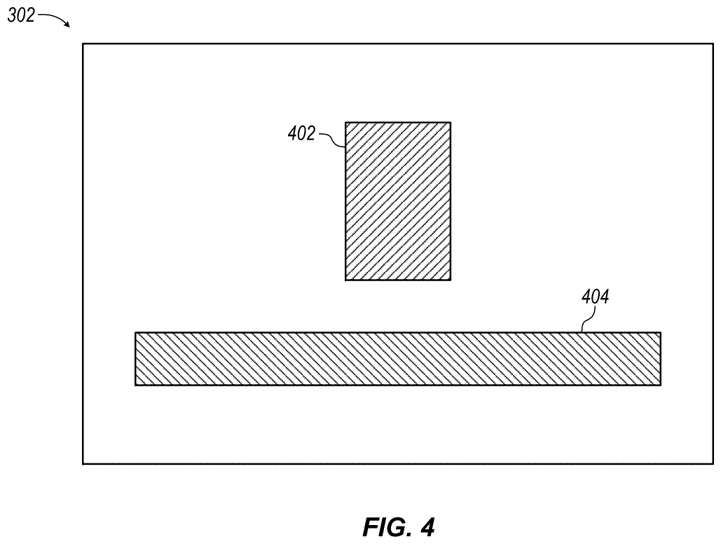

FIG. 4 is a schematic illustration of an example image frame 302. In various implementations, the supervisory application 136 segments the image frame 302 into multiple regions, such as region 402 and region 404. Segmentation may be performed according to geometry, for example by assigning predetermined portions of the image frame to represent areas where the plasma jet and printed film are expected to appear. In other examples, segmentation may involve partitioning the image frame 302 into pixel subsets grouped by intensity or spatial features using computer vision techniques such as thresholding, edge detection, or clustering. The plasma jet region 402 may represent the portion of the frame that corresponds to the plasma stream generated by the nozzle assembly 108, while the printed film region 404 may represent the portion of the frame that corresponds to deposited material on the substrate surface.

Referring back to FIG. 3, the preprocessor 306 receives the image frame 302 as input, processes the image frame 302, and outputs a preprocessed image frame 314. In various implementations, the preprocessor 306 performs operations to standardize and partition the image frame 302 for subsequent feature extraction. Such operations may include adjusting pixel resolution, normalizing pixel values, resizing the image frame to a fixed dimension, dividing the image frame 302 into a plurality of subregions, etc. In some examples, the image frame 302 may be segmented into regions, such as a plasma jet region and a printed film region, prior to preprocessing. In other examples, the image frame 302 is not segmented, and the preprocessor 306 processes the entire frame without distinction of regions.

The preprocessed image frame 314 may then be provided to the feature extractor 308, which generates embeddings 316. In various implementations, the feature extractor 308 includes a neural network trained to represent image data as feature vectors within a latent space. While the neural network may operate on the entire image frame, intermediate layers may yield feature vectors corresponding to localized receptive fields of the image. These vectors may be interpreted as patch-level representations that capture structural, textural, or intensity-based characteristics of local portions of the frame. The resulting embeddings 316 therefore provide a collection of numerical representations suitable for comparison against representative feature vectors stored in the feature bank 310.

The feature bank 310 includes a stored collection of reference features 318 that represent nominal operating conditions. In various implementations, the reference features 318 are generated during training from embeddings associated with image frames that correspond to non-anomalous states of the plasma jet or printed film. The feature bank 310 may therefore provide a repository of representative feature vectors that characterize expected behavior under nominal operation.

The embeddings 316 generated by the feature extractor 308 and the reference features 318 from the feature bank 310 are provided to the anomaly scorer 312. In various implementations, the anomaly scorer 312 includes logic configured to compute a similarity or distance metric between the embeddings 316 and the reference features 318. Suitable metrics may include nearest-neighbor distance, density estimation, or reconstruction error values. In various implementations, the anomaly scorer 312 implements nearest-neighbor comparison logic and computes an anomaly score based on a distance between an embedding 316 (e.g., representing a local receptive field of the image frame) and a corresponding reference feature 318 (e.g., a nearest feature vector in the feature bank 310). The anomaly scorer 312 may assign an anomaly score 304 to each embedding 316 based on the computed comparison.

The anomaly scores 304 may represent numerical values that quantify deviation from nominal conditions. In some examples, anomaly scores associated with embeddings that correspond to localized receptive fields may be aggregated across the plasma jet region and the printed film region to provide region-level assessments. In other examples, anomaly scores are combined across all embeddings corresponding to the entire image frame 302 to generate a global anomaly measure. Higher anomaly scores 304 may correspond to greater deviation from expected operation, for example indicating irregularities in plasma jet propagation or defects in printed film morphology.

In various implementations, the anomaly scores 304 may include structured outputs such as an anomaly heatmap. A heatmap representation may assign a numerical anomaly score to embeddings associated with particular receptive fields of the image frame 302, with values encoded as color intensity to visualize spatial distributions of anomalies. In some examples, the anomaly heatmap highlights local deviations within the plasma jet region or the printed film region, providing diagnostic information about plume dynamics or deposited film morphology. In other examples, the anomaly heatmap is aggregated to compute region-level scores, where a single score represents the overall anomaly level for the plasma jet region and another score represents the anomaly level for the printed film region. In further examples, anomaly scores may be combined across all embeddings derived from the image frame 302 to produce a frame-level assessment of operational conditions. The anomaly scores 304 may therefore provide both localized and global indicators of deviation from nominal operation, supporting downstream monitoring, analysis, or control actions.

Thus, the machine learning model 138 receives image frames 302 representing operation of the nozzle assembly 108 and outputs anomaly scores 304 representing deviations in a plasma jet region and a printed film region. The plasma jet region corresponds to the portion of the frame where the plasma stream is observed, and deviations in this region may represent abnormalities in the jet such as plume instabilities or discharge irregularities. The printed film region corresponds to the portion of the frame where deposited material forms on the substrate, and deviations in this region may represent abnormalities in the film such as defects, surface roughness, or non-uniform deposition.

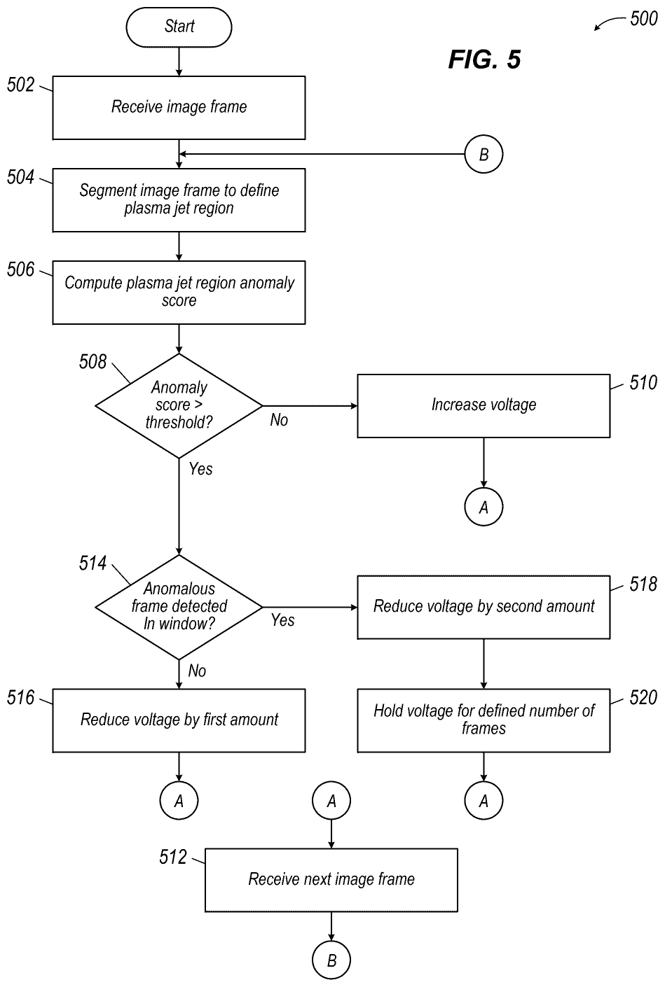

FIG. 5 is a flowchart illustrating an example process 500 for automatically controlling a voltage supplied to the nozzle assembly 108. In the example process 500, the supervisory application 136 receives an image frame from the sensors 114 (at operation 502). The sensors 114 may monitor the nozzle assembly 108 and the substrate during a printing process, and the image frame may represent a snapshot of the plasma jet and the substrate at a moment in time. In the example process 500, the supervisory application 136 segments the image frame to define a plasma jet region, for example according to any of the previously described techniques (at operation 504). The segmented image frame is then provided to the machine learning model 138, which generates a plasma jet region anomaly score (at operation 506).

In the example process 500, the supervisory application 136 evaluates the anomaly score against a threshold at logical decision 508. In various implementations, the threshold represents a predetermined numerical value established during training, a statistical percentile of nominal feature distributions, or a dynamic value adjusted according to recent operating conditions, and the threshold may serve as an acceptance criterion for continued operation of the plasma jet region. When the plasma jet region anomaly score is below the threshold, the score may represent operation within nominal limits of plume stability and discharge uniformity. When the plasma jet region anomaly score is above the threshold, the score may represent deviation from nominal limits, for example indicating plume instabilities, irregular discharge behavior, or other abnormalities that affect plasma jet quality.

In response to determining that the plasma jet region anomaly score does not exceed the threshold (“No” at logical decision 508), the supervisory application 136 commands the power control application 134 to adjust the voltage supplied to the electrodes 248 and 250 by a determined amount (at operation 510). In various implementations, the determined amount represents an incremental increase, for example on the order of tens to hundreds of volts, to compensate for minor fluctuations in plasma jet stability. In some examples, the determined amount may be selected from a range between about 0.05 kilovolts and about 1 kilovolt (for instance, about 0.1 kilovolts), depending on recent operational history of the plasma jet. Suitable ranges of voltage increase may therefore include relatively small steps sufficient to stabilize the discharge while avoiding excessive overcorrection.

Following the adjustment, in the example process 500, the supervisory application 136 receives a subsequent image frame from the sensors 114 (at operation 512) and segments the subsequent image frame to define the plasma jet region (at operation 504).

In response to determining that the anomaly score exceeds the threshold (“Yes” at logical decision 508), the supervisory application 136 evaluates whether a previously anomalous frame was detected within a window (at logical decision 514). In various implementations, the window defines a temporal range of consecutive frames, for example between 2 frames and 100 frames immediately preceding the current frame. In other examples, the window corresponds to a rolling time interval, such as between about 10 milliseconds and about 2 seconds prior to acquisition of the current frame. Detection of a previously anomalous frame within the window may represent persistence of plasma jet irregularities, while the absence of a previously anomalous frame within the window may represent an isolated event.

In response to determining that a previously anomalous frame was not detected within the window (“No” at logical decision 514), the supervisory application 136 commands the power control application 134 to reduce the voltage supplied to the electrodes 248 and 250 by a first amount (at operation 516). In various implementations, the first amount represents a relatively larger decrement intended to correct for an isolated deviation. Suitable first amounts may include values between about 0.1 kilovolts and about 2 kilovolts, for example about 0.5 kilovolts. The range of adjustment may be selected according to operating conditions of the nozzle assembly 108, with larger decrements suitable for higher applied voltages. Following the adjustment, in the example process 500, the supervisory application 136 receives a subsequent image frame from the sensors 114 (at operation 512) and segments the subsequent image frame to define the plasma jet region (at operation 504).

In response to determining that a previously anomalous frame was detected within the window (“Yes” at logical decision 514), the supervisory application 136 commands the power control application 134 to reduce the voltage supplied to the electrodes 248 and 250 by a second amount (at operation 518). In various implementations, the second amount is less than the first amount and is intended to apply a more conservative correction during persistent deviations. Suitable second amounts may include values between about 0.05 kilovolts and about 1 kilovolt, for example about 0.2 kilovolts. In the example process 500, the supervisory application 136 commands the power control application 134 to hold the adjusted voltage steady for a defined number of frames (at operation 520). In various implementations, the hold period may include between 2 and 50 frames, or a rolling temporal interval between about 10 milliseconds and about 1 second, depending on sensor frame rate and process stability. The supervisory application 136 then receives a subsequent image frame from the sensors 114 (at operation 512) and segments the subsequent image frame to define the plasma jet region (at operation 504).

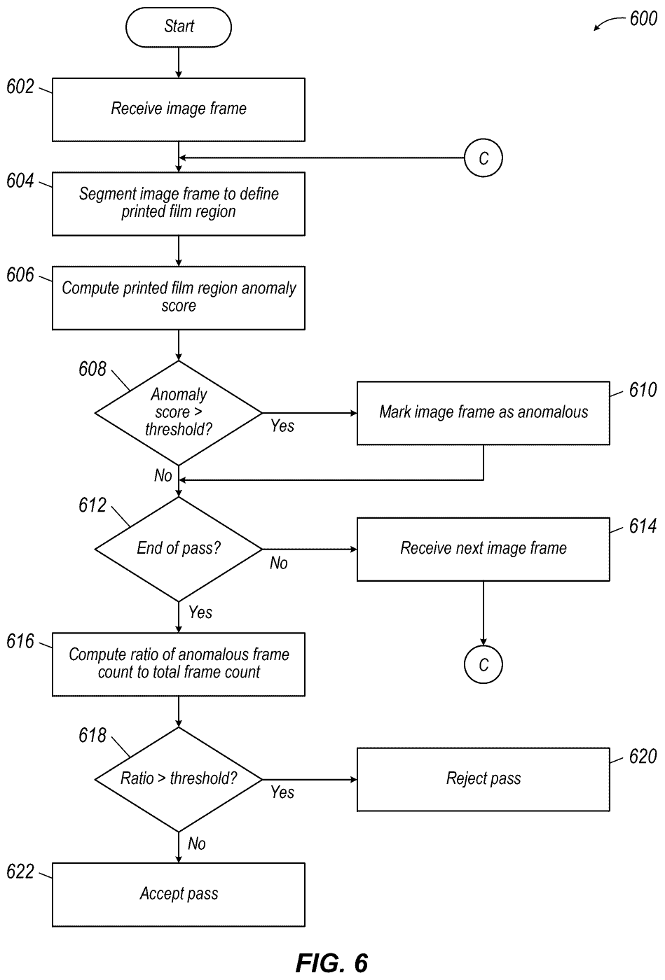

FIG. 6 is a flowchart illustrating an example process 600 for automatically controlling printing passes. A printing pass may refer to a continuous traversal of the nozzle assembly 108 relative to the substrate during which material is deposited and exposed to plasma treatment. A printing pass may begin when the nozzle assembly 108 initiates motion along a defined path over the substrate and may conclude when the nozzle assembly 108 reaches an endpoint of that path. In some examples, a printing pass corresponds to deposition of a single scan line or vector, which may represent only a portion of a layer on the substrate. In other examples, multiple printing passes are combined sequentially to complete a full layer, for example by rastering adjacent lines or overlapping paths. In further examples, a printing pass may be repeated over a same region of the substrate to increase thickness or improve uniformity of a deposited film.

A printing pass may therefore vary depending on process parameters. For example, a printing pass may correspond to a portion of a layer, a full layer, or multiple passes that collectively contribute to one or more layers of deposited material. The duration and length of a printing pass may also vary with printing resolution, substrate geometry, or motion control parameters.

In various implementations, execution of a printing pass is directed by the supervisory application 136. The supervisory application 136 may generate coordinated commands to one or more control applications of the control platform 116 to carry out deposition and plasma treatment during the pass. For example, the supervisory application 136 may transmit commands to the motion control application 132 to drive the nozzle assembly 108 along a predetermined path relative to the substrate. In parallel, the supervisory application 136 may transmit commands to the gas flow control application 130 to regulate carrier, sheath, and working gas flow rates in order to maintain a stable aerosol stream and plasma jet during traversal. In further examples, the supervisory application 136 may transmit commands to the power control application 134 to adjust applied voltage, frequency, or duty cycle to sustain plasma discharge while material is being deposited.

Through such coordinated control, the supervisory application 136 directs the combined gas flow, mechanical motion, and plasma discharge parameters that define a printing pass. In various implementations, this coordinated operation may maintain consistent deposition width, film thickness, or sintering quality along the length of the pass.

In the example process 600, the supervisory application 136 receives an image frame from the sensors 114 during execution of a printing pass, for example at the beginning of the printing pass or at an intermediate point of the printing pass (at operation 602). In the example process 600, the supervisory application 136 segments the image frame to define the printed film region, for example according to any of the previously described techniques (at operation 604). In the example process 600, the supervisory application 136 provides the segmented image frame to the machine learning model 138, which computes and returns a printed film region anomaly score (at operation 606).

In response to the printed film region anomaly score exceeding a threshold (“Yes” at logical decision 608), the supervisory application 136 marks the image frame as anomalous (at operation 610). In various implementations, the threshold represents a predetermined numerical value established during training, a statistical percentile of nominal feature distributions, or a dynamic value adjusted according to recent operating conditions, and the threshold may serve as an acceptance criterion for determining whether the printed film region of the current printing pass is acceptable. Suitable threshold values may include, for example, anomaly scores exceeding a normalized distance metric between about 0.5 and about 2.0, or statistical deviations greater than about two standard deviations from a nominal distribution.

In the example process 600, the supervisory application 136 determines whether the current printing pass is at the end (at logical decision 612). In response to the printed film region anomaly score not exceeding a threshold (“No” at logical decision 608), the supervisory application 136 determines whether the current printing pass is at the end (at logical decision 612).

In response to determining that the current printing pass is not at the end (“No” at logical decision 612), the supervisory application 136 receives the next image frame from the sensors 114 (at operation 614) and segments the image frame to define the printed film region (at operation 604). In response to determining that the current printing pass is at the end (“Yes” at logical decision 612), the supervisory application 136 computes a ratio of anomalous frame count to total frame count for the printing pass (at operation 616). In various implementations, the ratio may be compared against a threshold representing a maximum acceptable proportion of anomalous frames. Suitable threshold values may include, for example, between about 5 percent and about 20 percent of total frames for the printing pass. In response to determining that the ratio exceeds the threshold (“Yes” at logical decision 618), the supervisory application 136 rejects the current printing pass (at operation 620).

In various implementations, rejecting the printing pass indicates that material deposited during the pass does not meet quality standards for inclusion in a final printed device. Remedial actions may be directed by the supervisory application 136 in response to rejecting the printing pass. For example, the supervisory application 136 may transmit commands to the motion control application 132 to reposition the nozzle assembly 108 for a repeat traversal of the same region, with the gas flow control application 130 and the power control application 134 adjusted to modify deposition or plasma treatment parameters. In other examples, the supervisory application 136 may direct the nozzle drive 112 to perform a corrective overprint that deposits an additional pass on top of the rejected pass in order to restore film thickness or uniformity.

In further implementations, the supervisory application 136 may apply a compensation mechanism in which a first new layer is deposited with the plasma stream disabled by withholding voltage from the electrodes, followed by a second new layer deposited with the plasma stream enabled by applying a pulsed voltage that exceeds a breakdown threshold of the plasma working gas. Additional remedial actions may include logging the rejected pass in a defect record stored in the storage 128, adjusting machine learning thresholds for subsequent passes, or scheduling removal of the deposited material by plasma etching or by another suitable rework operation. Through such remedial actions, the supervisory application 136 may support maintenance of overall print quality despite localized defects.

In response to determining that the ratio of anomalous frame count to total frame count does not exceed the threshold (“No” at logical decision 618), the supervisory application 136 accepts the current printing pass (at operation 622). For example, the supervisory application 136 may proceed to the next printing pass. Thus, the threshold may serve as an acceptance criterion for inclusion of the printing pass in the printed structure.

The following experimental validation and example implementations section provide specific examples illustrating the performance of various configurations of the co-jet printing system 100. In particular, these examples demonstrate how the configuration of the nozzle assembly 108 of FIGS. 2A and 2B, together with the system-level components of FIG. 1, facilitates stable gas flow, plasma jet generation, and concurrent aerosol deposition with in situ sintering across a variety of substrates and operating conditions.

### EXPERIMENTAL EXAMPLES AND EXAMPLE IMPLEMENTATIONS

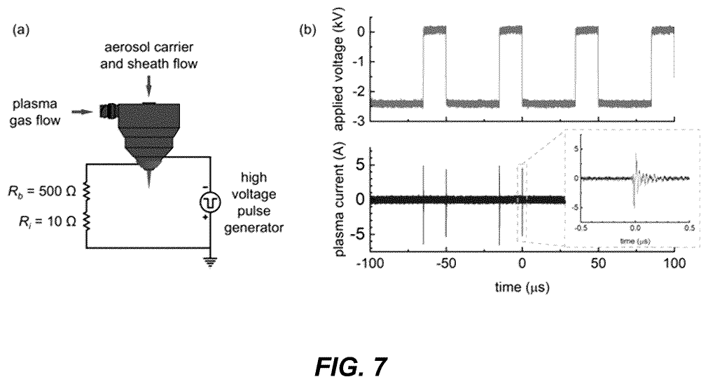

FIG. 7 illustrates an example electrical characterization of the plasma jet. In the schematic illustrated in inset (a) of FIG. 7, a ballast resistor Rb of approximately 500Ω was incorporated into the power supply 110 to limit discharge current, and a resistor Ri of approximately 10Ω was used to monitor plasma current by measuring voltage across Ri. In various implementations, when the pulsed potential applied across electrodes 248 and 250 exceeds a breakdown threshold of the working gas supplied from the working gas supply 106, ionization initiates and propagates as surface ionization waves along interior walls of the nozzle body 204 before extending downstream as plasma streamers. The streamers propagate along a flow path defined by the annular jet of the working gas until reaching a substrate surface. Inset (b) of FIG. 7 shows representative applied voltage and plasma current traces measured during operation at a pulsed voltage of approximately −2.5 kV, a frequency of 20 kHz, and a duty cycle of about 30 percent.

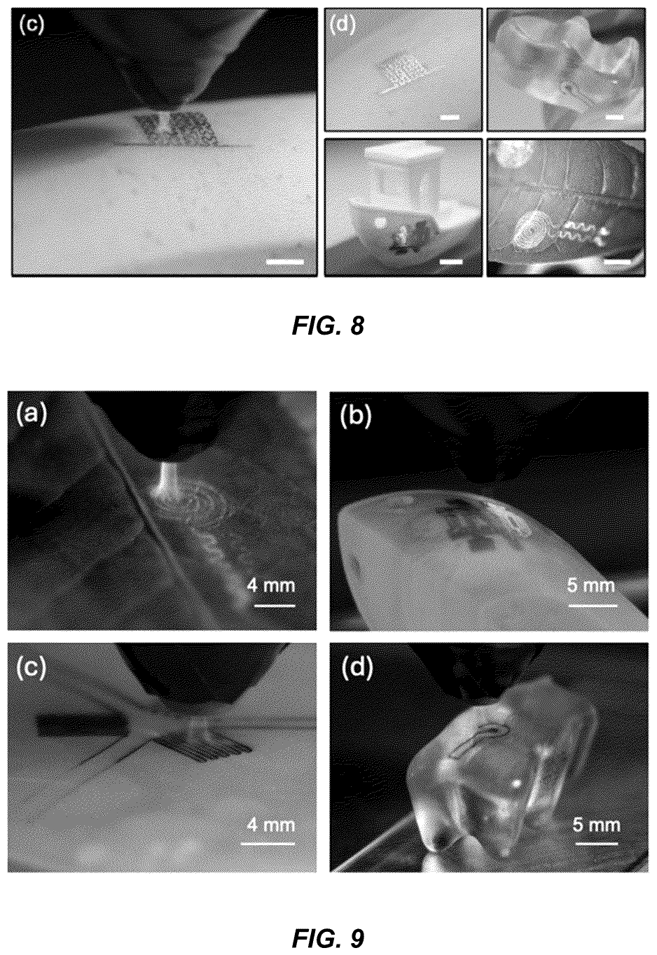

FIG. 8 provides example photographs demonstrating co-jet printing of silver nanoparticle ink. Inset (c) of FIG. 8 illustrates co-jet printing of conductive traces directly on the surface of a banana. Inset (d) of FIG. 8 illustrates conductive silver features deposited directly on a banana (top left), on a gelatin substrate (top right), on a three-dimensional polylactic acid (PLA) benchmark structure (bottom left), and on a plant leaf (bottom right). Scale bars for insets (c) and (d) of FIG. 8 represent approximately 5 mm. In various implementations, the decoupled aerosol and plasma flow paths of nozzle assembly 108 support independent adjustment of carrier, sheath, and working gas conditions, thereby accommodating diverse substrates and ink formulations. Direct deposition of conductive silver features on natural, soft, and synthetic materials demonstrates compatibility with temperature-sensitive substrates such as biological tissue, gelatin, elastomers, and polymers.

FIG. 9 illustrates additional example implementations of co-jet printing. The series shows deposition of silver nanoparticle ink on inset (a) of FIG. 9 a plant leaf, inset (b) of FIG. 9 a representative PLA artifact fabricated by additive manufacturing, inset (c) of FIG. 9 a silicone rubber membrane, and inset (d) of FIG. 9 a gelatin substrate. These examples demonstrate that concurrent deposition and in situ plasma sintering support patterning on non-planar, soft, and living substrates, further extending applications of co-jet printing to flexible electronics, biohybrid platforms, and wearable devices.

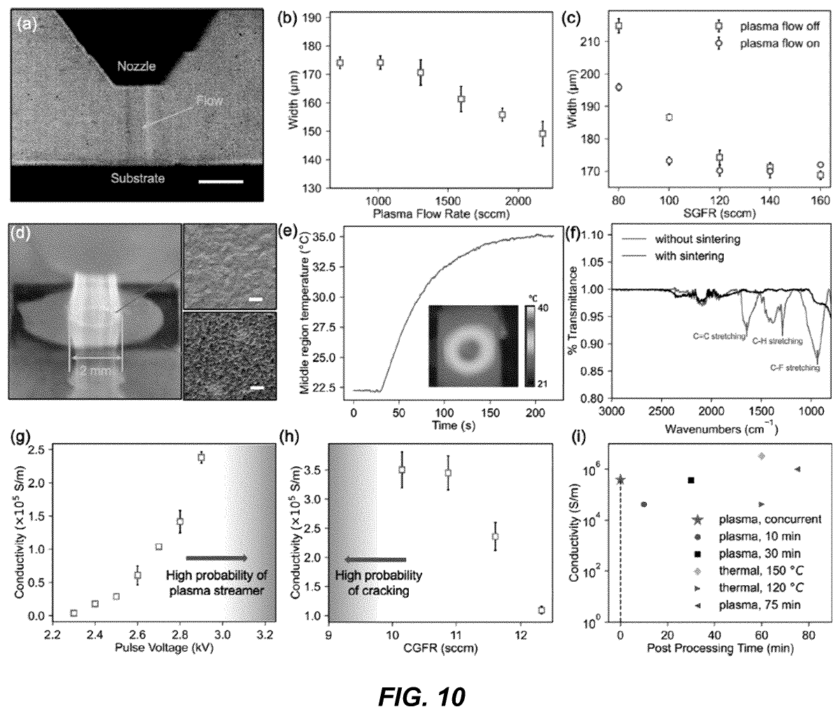

FIG. 10 illustrates example characterizations of the co-jet printing system 100. In the example of inset (a) of FIG. 10, Schlieren imaging shows density gradients of combined gas flows exiting the nozzle assembly 108. The image demonstrates that the carrier gas, sheath gas, and working gas streams remain substantially laminar over a distance exceeding approximately 10 mm, which is greater than the typical working distance between outlets 240 and 246 and a substrate. Scale bar is approximately 4 mm.

In various implementations, process parameters may be characterized by printing line width as a function of plasma working gas flow rate at a constant sheath gas flow rate, as shown in inset (b) of FIG. 10, or as a function of sheath gas flow rate with and without the plasma working gas flow, as shown in inset (c) of FIG. 10. In some examples, morphological effects of plasma treatment may be observed by imaging printed films near and away from the plasma impingement point. Insect (d) of FIG. 10 shows example plasma jet shapes and scanning electron microscopy images of silver films within approximately 1 mm of the plasma impingement point (top) and at approximately 3 mm radius outside the impingement point (bottom). Scale bars are approximately 10 μm.

Additional characterizations of plasma interaction with deposited films are shown in insets (c) through (i) of FIG. 10. Inset (e) of FIG. 10 illustrates temperature variation measured in the substrate region exposed to the plasma jet during a continuous exposure of approximately 200 seconds. Inset (f) of FIG. 10 illustrates Fourier transform infrared spectroscopy results comparing unsintered aerosol-deposited films and co-jet printed films, showing removal of organic components associated with surfactants in the ink. Inset (g) of FIG. 10 illustrates conductivity of printed films versus applied plasma pulse voltage, while inset (h) of FIG. 10 illustrates conductivity versus carrier gas flow rate. Error bars in insets (g) and (h) of FIG. 10 represent random variations in conductivity among samples fabricated under identical parameters. Inset (i) of FIG. 10 illustrates conductivity versus post-processing time for silver films fabricated by co-jet printing compared with other methods.

These experimental validations demonstrate, for example, that the coaxial configuration of the nozzle assembly 108 supports stable laminar flow and concurrent deposition with in situ plasma sintering. In various implementations, the system 100 may provide repeatable electrical performance of printed metallic films while maintaining near-ambient substrate temperatures, supporting fabrication on temperature-sensitive and non-planar substrates.

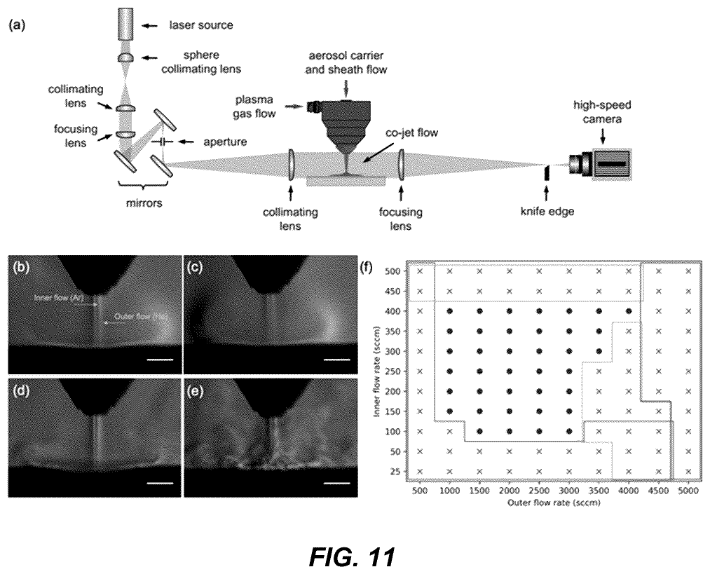

FIG. 11 illustrates example Schlieren imaging characterizations of combined gas flows exiting the nozzle assembly 108. In the schematic of inset (a) of FIG. 11, the nozzle assembly 108 may be positioned approximately 10 mm above a glass substrate. In various implementations, Schlieren imaging may be used to visualize flow regimes under different inner and outer gas conditions. Inset (b) of FIG. 11 illustrates an example with an inner flow of approximately 150 sccm and an outer flow of approximately 2000 sccm, showing a substantially laminar co-jet both before and after interaction with the glass substrate. Inset (c) of FIG. 11 illustrates an example with an inner flow of approximately 25 sccm and an outer flow of approximately 2000 sccm, where the inner flow mixes with the outer flow shortly after exiting the outlets 240 and 246 of the nozzle body 204. Inset (d) of FIG. 11 illustrates an example with an inner flow of approximately 500 sccm and an outer flow of approximately 2000 sccm, maintaining laminar propagation in flight but exhibiting instability at the substrate. Inset (e) of FIG. 11 illustrates an example with an inner flow of approximately 200 sccm and an outer flow of approximately 5000 sccm, where turbulence develops before reaching the substrate.

Inset (f) of FIG. 11 provides a representative operating map of inner and outer flow rates. In some examples, stable laminar operation is denoted by blue markers, while red markers indicate non-ideal flow behaviors. Within the map, markers in a green region correspond to early mixing of flows prior to reaching the substrate, markers in an orange region correspond to instability developing after impingement on the substrate, and markers in a purple region correspond to turbulent flow conditions.

Returning to FIG. 10, additional characterizations illustrate example effects of gas flow conditions on deposition resolution. In various implementations, sheath gas flow from the sheath gas supply 104 focuses an aerosol stream into a confined jet, as described above. The introduction of a plasma working gas flow from the working gas supply 106 may preserve this aerodynamic focusing effect. Inset (b) of FIG. 10 illustrates an example in which increasing the plasma working gas flow reduces line width at a constant sheath gas flow rate, thereby enhancing deposition resolution on a glass substrate.

Inset (c) of FIG. 10 illustrates printed line widths under various sheath gas flow rates with and without a coaxial plasma working gas flow. In some examples, at lower sheath gas flow rates, inclusion of the plasma working gas flow results in narrower line widths compared to deposition with sheath gas alone. At higher sheath gas flow rates, line widths converge to values obtained with sheath gas flow only.

After impingement on a dielectric substrate, the plasma jet generated between electrodes 248 and 250 may induce radially propagating surface ionization waves along the substrate surface. These waves may create a circular region of plasma interaction where sintering of deposited material occurs. In various implementations, the extent of effective sintering may be characterized by scanning electron microscopy at locations across a printed film. Inset (d) of FIG. 10 illustrates an example film of silver nanoparticles printed over an area of approximately 6 mm by 6 mm and post-sintered by positioning the plasma jet stationarily above the film center. The most significant sintering is observed directly at the plasma-substrate impingement point within a region of approximately 2 mm diameter. Due to surface ionization wave propagation, sintering effects extend radially outward to approximately 6 mm diameter, with decreasing uniformity at larger radii. These results demonstrate, for example, that both concurrently deposited aerosols and previously deposited material in adjacent regions undergo plasma-assisted sintering, with increased exposure duration supporting greater sintering efficacy.

Inset (c) of FIG. 10 illustrates example time-resolved infrared camera measurements characterizing substrate temperature during co-jet printing. In the example, the average temperature of a glass substrate region processed by the plasma jet increases from ambient conditions to approximately 35° C. over a duration of about two minutes before reaching a steady state due to balance between energy input and dissipation. In various implementations, the observed temperature rise may vary depending on substrate composition. As demonstrated in FIGS. 8 and 9, printing on organic and biological substrates maintained surface temperatures below thresholds for thermal sensitivity, consistent with the near-ambient nature of system 100 operation.

Inset (f) of FIG. 10 illustrates example Fourier-transform infrared spectroscopy measurements comparing aerosol-deposited films without plasma exposure and films fabricated by co-jet printing. In some examples, absorption peaks associated with surfactant groups in the ink, including a C═C stretching band near 1645 cm⁻¹, a C—H stretching band near 1288 cm⁻¹, and a C—F stretching band near 940 cm 1, are removed following co-jet processing. These results demonstrate that reactive plasma species interact with deposited nanoparticles to remove organic surfactants and promote in situ sintering.

Inset (g) of FIG. 10 illustrates conductivity of printed silver films as a function of plasma pulse voltage supplied by the power supply 110. In various implementations, increasing the pulse voltage from approximately 2.3 kV to approximately 2.9 kV produces an increase in conductivity by about two orders of magnitude when other parameters are maintained constant. At voltages exceeding approximately 2.9 kV, the discharge may transition to a regime dominated by a single strong streamer, accompanied by increased thermalization of the plasma and elevated risk of breakdown of the nozzle body 204 or deposited film.

Inset (h) of FIG. 10 illustrates conductivity of printed films as a function of aerosol carrier gas flow rate from the carrier gas source 102. In some examples, decreasing the carrier gas flow rate from approximately 12.3 sccm to approximately 10.2 sccm results in an increase in conductivity by a factor of about 3.5. Further reductions in carrier gas flow rate may reduce deposition uniformity, producing voids in the film. Local electric field enhancement at void edges may attract charged plasma species, resulting in etching and eventual crack formation. In various implementations, lower deposition rates support thinner layers that undergo more uniform plasma interaction during each pass, promoting improved in situ sintering depth compared to ex situ plasma treatments.

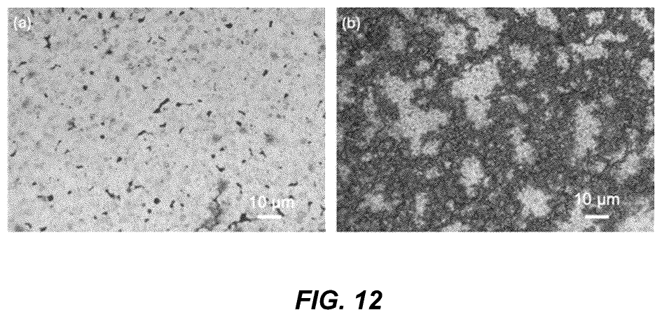

FIG. 12 illustrates example microscope images of silver nanoparticle films printed under different carrier gas flow conditions. Inset (a) of FIG. 12 shows a film deposited at a low carrier gas flow rate of approximately 7.3 sccm, where voids are observed in the deposited structure. Inset (b) of FIG. 12 shows the corresponding film following plasma jet sintering at a plasma working gas flow rate of approximately 1500 sccm and a plasma pulse voltage of approximately −2.7 kV applied by the power supply 110. Cracks are observed to form at the locations of the voids, consistent with local field enhancement and etching effects described above in relation to inset (h) of FIG. 10.

Inset (i) of FIG. 10 illustrates conductivity of silver films fabricated by co-jet printing compared with conductivity of silver films fabricated using post-printing plasma sintering and thermal sintering. In various implementations, the conductivity of co-jet printed films is comparable to that of post-printing plasma sintering performed for approximately 30 minutes and exceeds the conductivity achieved by thermal sintering at approximately 120° C. for 60 minutes. These results demonstrate that system 100 may achieve in situ sintering during printing at near-ambient temperature without additional post-processing steps.

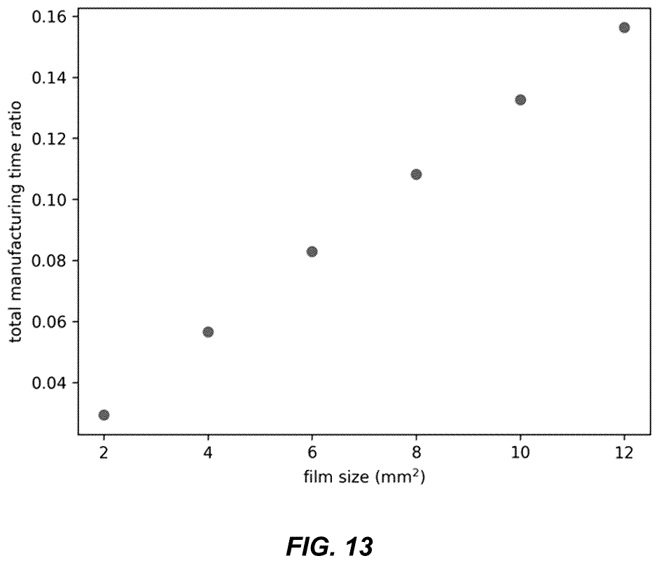

FIG. 13 illustrates example manufacturing time comparisons between co-jet printing and conventional processes. The chart of FIG. 13 shows total manufacturing time ratio as a function of printed film size, where the ratio α is defined as α=t_{CJP}/(t_{AJP}+tₛᵢₙₜₑᵣ). In the example, t_{CJP} represents total manufacturing time of a film printed using co-jet printing with silver nanoparticle ink, t_{AJP} represents printing time of a film fabricated by aerosol jet printing without plasma, and tₛᵢₙₜₑᵣ represents post-printing thermal sintering time. In some examples, three layers are deposited for co-jet printed films and two layers are deposited for conventional films. Process conditions for both cases included an infill line spacing of approximately 0.04 μm and a printing speed of approximately 1 mm/s. Results of FIG. 13 show that elimination of post-printing sintering by co-jet processing supports reductions in overall manufacturing time by factors that increase with film size decreases.

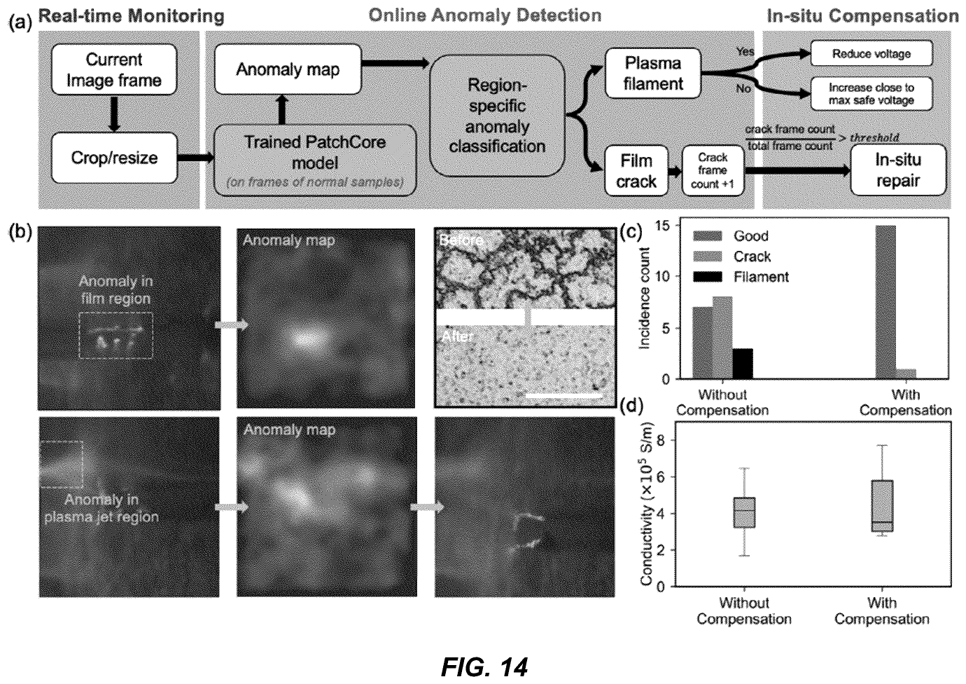

FIG. 14 illustrates example implementations of in situ defect detection and compensation integrated with the co-jet printing process. Inset (a) of FIG. 14 schematically depicts a machine learning-based real-time monitoring configuration for region-specific anomaly detection and compensation. Inset (b) of FIG. 14 provides representative image frames identifying anomalies, where the top sequence illustrates detection of cracks in deposited films and the bottom sequence illustrates detection of plasma filamentation. The scale bar is approximately 10 μm. Inset (c) of FIG. 14 illustrates yield improvement associated with in situ monitoring and correction, while inset (d) of FIG. 14 compares conductivity of silver films printed with and without in situ compensation.

The co-jet printing process involves complex interactions between aerosol deposition and plasma jet sintering, where plasma jet instability may influence yield and conductivity. In various implementations, increased plasma pulse voltage improves conductivity of metallic films but also increases the likelihood of streamer formation, leading to localized damage. To address these competing effects, in situ monitoring may incorporate a live inspection camera coupled with a region-specific anomaly detection algorithm, as depicted in inset (a) of FIG. 14. The supervisory application 136 described above receives image frames from the sensors 114 and applies the machine learning model 138 to detect anomalies in both the plasma jet region and the printed film region. Detection of anomalies such as streamer formation or crack propagation may trigger corrective adjustments through the power control application 134 or activation of compensation passes, thereby supporting higher reproducibility.

In some examples, the anomaly detection algorithm includes a PatchCore machine learning model trained on nominal image frames. During training, patch-level features are extracted from image frames representing non-anomalous conditions and stored in a memory bank, with coreset sampling applied to reduce dimensionality. During inference, the machine learning model computes pixel-level anomaly scores by nearest-neighbor comparison of features from live frames to those in the memory bank. Segmentation of the image frames into a plasma jet region and a printed film region allows region-specific detection of anomalies such as streamer formation in the plasma or cracking in the deposited film, consistent with the implementations described in relation to FIGS. 3-6.

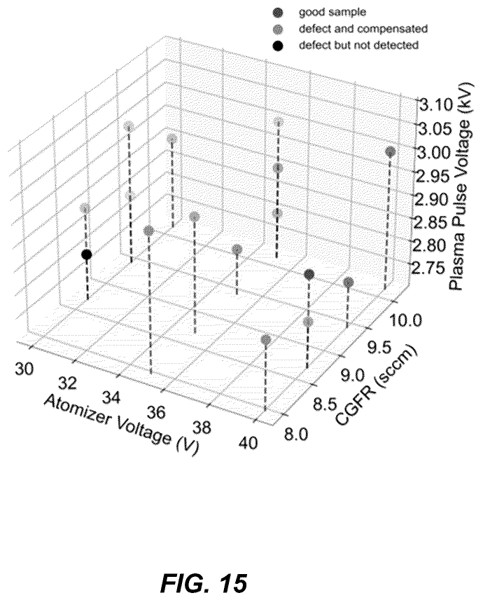

During operation, the PatchCore anomaly detection model is integrated into the live monitoring system, continuously producing anomaly maps at a per-frame basis, as shown in inset (a) of FIG. 14. When the plasma jet region exhibits an anomaly, the applied pulse voltage from the power supply 110 may be reduced in increments of approximately 0.5 kilovolts. When no anomaly is present, the applied voltage may instead be gradually increased in increments of approximately 0.1 kilovolts until reaching a stability limit, after which the voltage may be reduced by approximately 0.2 kilovolts as the printed features are gradually sintered. When the printed film region is identified as anomalous, frames are marked accordingly and an anomaly ratio is computed across a printing pass. In some examples, when the anomaly ratio exceeds a defined threshold, corrective actions include deposition of a new compensating layer without plasma exposure, followed by deposition of a subsequent layer with concurrent plasma jet sintering. Inset (b) of FIG. 14 illustrates representative anomaly frames: the first row shows crack detection and subsequent repair, and the second row shows streamer detection and mitigation by adjustment of pulse voltage. Experimental validation of these methods is presented in FIG. 15.

FIG. 15 illustrates a distribution of example samples printed with randomly generated printing parameters with their online detection and compensation results. Sixteen samples may be fabricated with randomly varied parameters within ranges prone to defect formation, including carrier gas flow rate between approximately 8 and 10 sccm and plasma pulse voltage between approximately 2.8 and 3.0 kV. Atomizer voltage may be varied between approximately 30 and 40 V to introduce drift effects. Without in situ monitoring, cracks were observed in 8 of the 16 samples and plasma streamer formation in 3 of the samples. With in situ monitoring and compensation, yield of defect-free films increased to approximately 94 percent, with only one cracked sample remaining undetected. Inset (c) of FIG. 14 summarizes yield improvements, while inset (d) of FIG. 14 shows conductivity comparisons indicating that films subjected to in situ correction exhibit conductivity comparable to films fabricated without defects. These results demonstrate that in situ monitoring and compensation may support improved reproducibility and electrical performance of films fabricated by co-jet printing.

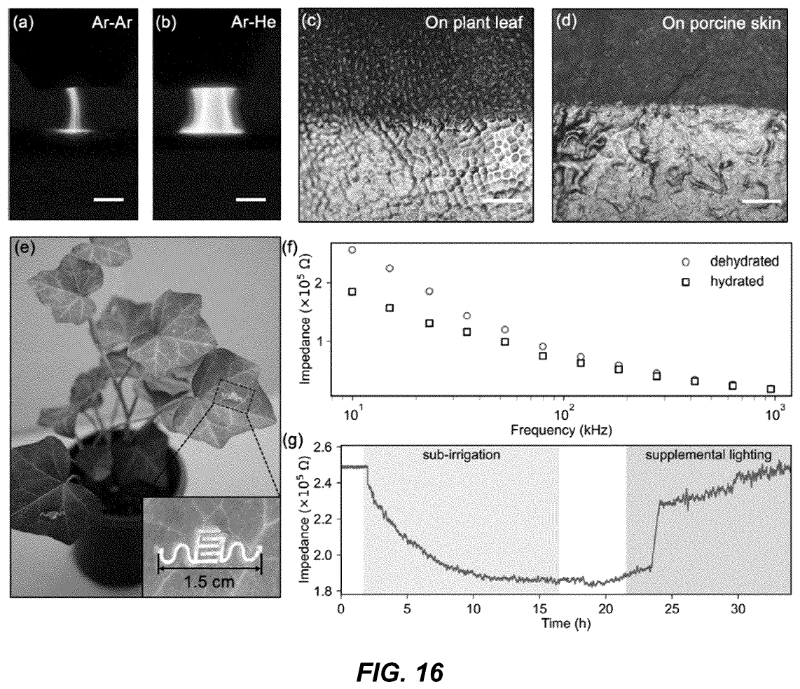

FIG. 16 illustrates example implementations of co-jet printing on biological materials. Inset (a) of FIG. 16 shows a plasma jet generated with argon supplied as both the aerosol sheath gas from the sheath gas supply 104 and the working gas from the working gas supply 106 during deposition on a plant leaf. Inset (b) of FIG. 16 shows a plasma jet generated with argon as the aerosol sheath gas and helium as the working gas under otherwise similar conditions, also during deposition on a plant leaf. Scale bars for insets (a) and (b) of FIG. 16 are approximately 2 mm. Inset (c) of FIG. 16 illustrates a microscope image of silver films printed on a plant leaf, and inset (d) of FIG. 16 illustrates silver films printed on porcine skin. Scale bars for insets (c) and (d) of FIG. 16 are approximately 200 μm, where the upper half of each image corresponds to uncoated substrate and the lower half corresponds to co-jet printed silver. Inset (c) of FIG. 16 illustrates a pot of English ivy incorporating hydration sensors printed directly on leaves. The inset of inset (e) shows a detailed view of a printed interdigitated silver electrode. Inset (f) of FIG. 16 illustrates impedance spectra of hydrated and dehydrated leaves measured under different frequencies, and inset (g) of FIG. 16 illustrates impedance shifts at approximately 10 kHz under controlled changes in hydration level.

As previously described, the co-jet printing system 100 supports deposition and concurrent sintering at or near ambient temperature, providing compatibility with temperature-sensitive and living substrates. In various implementations, this capability may address limitations of conventional additive manufacturing processes for direct printing of functional devices on biotic interfaces. For example, direct deposition of metallic features on plant and animal substrates supports applications in biohybrid systems, environmental monitoring, and wearable sensing.

In some examples, the decoupling of the aerosol stream and plasma jet described in relation to nozzle assembly 108 supports independent selection of gas compositions for sheath gas and working gas. Early development used argon as both sheath and working gas for cost efficiency. However, when the substrate includes a water-containing biological interface, the plasma jet with argon as working gas may exhibit filamentation and streamer attachment to the substrate surface. In various implementations, replacement of the working gas with helium while maintaining argon as sheath gas stabilizes the discharge, producing a glow-like plasma jet even in contact with water-containing substrates, as shown in insets (a) and (b) of FIG. 16.

In some examples, printing over biological substrates under helium working gas conditions yields silver films with conductivity of approximately 1.2×10⁶ S·m⁻¹, which is greater than conductivity values observed on polymer or glass substrates under similar conditions. This increase is attributed to enhanced plasma-substrate interactions at biological interfaces. For example, the conductive and hydrated nature of biological substrates may increase current flow through the plasma channel, resulting in elevated densities of reactive plasma species and photons that promote more effective nanoparticle sintering. In addition, porosity and surface morphology of biological materials may further influence plasma discharge behavior and enhance local coupling between the plasma jet and deposited nanoparticle ink.

In various implementations, direct fabrication of nanoscale materials on biological interfaces using co-jet printing (CJP) provides advantages compared with transfer-after-fabrication processes. For example, deposition from a nanoparticle-containing aerosol followed by in situ plasma jet sintering supports three-dimensional conformity and intimate contact with biological substrates. As illustrated in insets (c) and (d) of FIG. 16, optical microscope images show silver films deposited on a leaf epidermis and porcine skin. The printed electrodes replicate microstructural features of the underlying biological surfaces, demonstrating conformal deposition that may support applications requiring low contact resistance or effective strain transfer. In some examples, this approach further reduces device weight and size, mitigating disruption to natural activity of plant or animal tissues. In other examples, integration of deposition and sintering into a single step supports higher levels of automation and repeatability by reducing operator-dependent variability in post-processing.

Experimental validation of direct printing on biological substrates is shown in inset (c) of FIG. 16. In this example, an interdigitated electrode pair may be printed on a leaf of a potted English ivy plant to function as a hydration sensor. The conformal contact between the printed electrodes and the leaf epidermis supports electrochemical impedance measurements of leaf hydration. Inset (f) of FIG. 16 illustrates impedance spectra under hydrated and dehydrated conditions, where differences are more pronounced at lower frequencies, indicating higher sensitivity in this regime. A frequency of approximately 10 kHz may be selected to monitor time-dependent hydration events, as illustrated in inset (g) of FIG. 16. In this example, impedance increased during a 24-hour dehydration period, decreased upon rehydration in a sub-irrigation system, and subsequently increased after removal from the water reservoir. Supplemental LED lighting introduced after rehydration produced a rapid impedance increase associated with photosynthetic water consumption, returning to a level similar to the dehydrated state after approximately 12.5 hours. These results suggest that co-jet printed hydration sensors support tracking of physiological processes with minimal disturbance of plant tissue.

Thus, integration of aerosol jet deposition with non-thermal plasma jet sintering in the co-jet printing (CJP) process supports direct and concurrent deposition and sintering of metallic nanomaterials at atmospheric pressure and near-ambient temperature. In various implementations, such processes produce electrical conductivity in printed metallic features comparable to conventional aerosol jet printed materials subjected to extended post-printing thermal sintering.

In some examples, a machine learning-directed monitoring and compensation method associated with the control platform 116 supports in situ detection of defects and execution of corrective actions. Such techniques may increase process reproducibility and yield, for example as previously described.

In various implementations, the CJP process supports direct fabrication of hydration sensors on living plant substrates. For example, interdigitated silver electrodes may be printed on English ivy leaves for hydration monitoring, as previously described. Such sensors track hydration-level changes with minimal disruption to biological activity, consistent with electrochemical impedance data, as previously described.

The versatility of CJP described herein supports integration of abiotic and biotic materials, creating opportunities in wearable devices, implantable systems, human-machine interfaces, and biohybrid platforms. In various implementations, extension of the CJP process to irregular or non-planar substrates may be supported by nozzle drive 112 architectures providing six degrees of freedom, such that the nozzle assembly 108 maintains a substantially perpendicular orientation and constant nozzle-to-substrate distance during printing.

### Additional Example Implementation Details

In some examples, an ink formulation used for co-jet printing includes a silver nanoparticle dispersion. For instance, a 12 percent w/w aqueous silver nanoparticle ink may be prepared by diluting a 50 percent w/w commercial silver nanoparticle ink (JS-A221AE, Novacentrix) with deionized water. In various implementations, the formulation further includes approximately 6 percent w/w ethylene glycol to modify viscosity and surface tension. For each printing task, approximately 1.2 mL of the prepared ink may be used. In some examples, approximately 9 μL of a defoamer (Five Star defoamer 105) may be introduced into the ink formulation to reduce bubble formation during atomization in the mixing chamber 120.

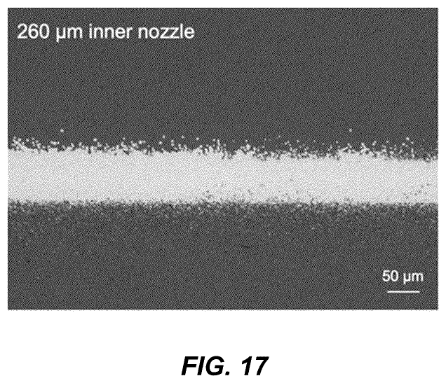

In various implementations, the co-jet nozzle assembly 108 may be fabricated by additive manufacturing techniques. For example, the inner and outer nozzle bodies may be printed with a stereolithography printer using a resin material (ELEGOO Standard 8K 3D Printer Resin). A brass sleeve (7473T192, McMaster) may be mounted on the inner nozzle and served as an electrode electrically coupled to the power supply 110. A copper wire (7940A91, McMaster) may be wrapped around the outer nozzle and served as a grounded electrode. The inner and outer nozzle components may be assembled concentrically and sealed with epoxy. The inner nozzle diameter in one implementation measured approximately 540 μm, and the outer nozzle diameter measured approximately 2.4 mm. In some examples, stereolithography fabrication produced an inner nozzle diameter as small as approximately 260 μm, corresponding to a minimum printed line width of about 60 μm, as illustrated in FIG. 17.

FIG. 17 illustrates an example line pattern printed using the co-jet printing process with an inner nozzle diameter of approximately 260 μm. In various implementations, process optimization for reduced nozzle size includes adjusting carrier gas, sheath gas, and working gas flow rates. For instance, inset (a) of FIG. 17 illustrates an example with sheath gas flow of approximately 50 sccm, carrier gas flow of approximately 8 sccm, and plasma working gas flow of approximately 1300 sccm.

In various implementations, plasma jet generation involves directing a plasma working gas from the working gas supply 106 through the outer annular path of the nozzle body 204. Flow of the plasma working gas may be regulated by flow metering hardware, for example a mass flow controller (FMA5518A, Omega Engineering). In some examples, a direct current power supply 110 (AU-5R120, Matsusada Precision Inc.) provides electrical energy to a pulse generator (PVX-4140-B, Berkeley Nucleonics Corp.) delivering pulsed voltages between approximately −3.2 kV and 0 kV. Unless otherwise specified, the plasma pulse voltage is maintained at approximately −2.9 kV. The pulse generator may be gated with a 5 V square waveform signal at a frequency of approximately 20 kHz and a duty cycle of approximately 30 percent, produced by a function generator (DG4062, RIGOL). In various implementations, electrical characteristics of the plasma jet are monitored by sensors 114 incorporating a digital oscilloscope (DS4024, RIGOL), providing diagnostic waveforms representative of plasma discharge behavior.

In some examples, Schlieren imaging is applied to visualize the co-jet flow exiting the nozzle assembly 108. A laser source (CAVILUX® Smart, 640 nm) provides collimated illumination across the interaction region between the co-jet flow and a glass substrate. Beams deflected by refractive index gradients within the flow may bypass a knife edge (FatMax Blade, 11-700A) and be recorded by sensors 114 including a high-speed camera (FASTCAM SA4, Photron) positioned parallel to the substrate surface. In one implementation, imaging may be performed at approximately 10³ frames per second. Undisturbed beams are intercepted by the knife edge, producing Schlieren contrast. The resulting images, as illustrated in inset (a) of FIG. 10, demonstrate variations in light intensity associated with density gradients in the combined gas flows. A schematic of the Schlieren imaging configuration is illustrated in inset (a) of FIG. 11.

In various implementations, characterization of the co-jet printing (CJP) process may be conducted on glass substrates (MSL3×1, United Scientific) cleaned with isopropyl alcohol prior to deposition. A silver nanoparticle ink formulation as described above may be used for all experiments. In one example, deposition may be performed under constant conditions including a printing speed of approximately 1 mm/s, an atomizer voltage of approximately 30 V applied to the atomizer 234, and an ink bath temperature of approximately 22° C. The plasma pulse frequency from the power supply 110 may be maintained at approximately 20 kHz with a duty cycle of approximately 30 percent. Argon may be supplied from both the sheath gas supply 104 and the working gas supply 106 as sheath gas and plasma working gas, respectively, as well as from the carrier gas source 102.

In some examples, effects of plasma working gas flow rate on printed line width may be investigated while maintaining sheath gas flow rate at approximately 120 sccm and carrier gas flow rate at approximately 8.7 sccm. In various implementations, effects of sheath gas flow rate on printed line width may be investigated with plasma working gas flow rate maintained at approximately 1000 sccm and carrier gas flow rate at approximately 8.7 sccm. In these implementations, four consecutive printing passes may be executed to form each line. A plasma pulse voltage of approximately −2.7 kV may be applied across electrodes 248 and 250 to initiate the plasma jet.

In further examples, effects of plasma pulse voltage on conductivity may be investigated with sheath gas flow rate maintained at approximately 120 sccm, plasma working gas flow rate maintained at approximately 1300 sccm, and carrier gas flow rate maintained at approximately 8.7 sccm. Effects of carrier gas flow rate on conductivity may be investigated with sheath gas flow rate maintained at approximately 120 sccm, plasma working gas flow rate maintained at approximately 1300 sccm, and plasma pulse voltage maintained at approximately −2.9 kV. Thickness of fabricated films varied according to printing and sintering parameters, as summarized in Table 1 below.

TABLE 1
Thickness of fabricated films under various
printing and sintering parameters.

| | | | Plasma | | |
|---|---|---|---|---|---|
| Sheath Gas | Carrier Gas | Plasma | Pulse | Number | Average |
| Flow Rate | Flow Rate | Flow Rate | Voltage | of | Thickness |
| (sccm) | (sccm) | (sccm) | (kV) | Layers | (μm, n = 3) |
| 120 | 8.7 | 1885 | −2.3 | 3 | 1.75 |
| 120 | 8.7 | 1885 | −2.4 | 3 | 1.90 |
| 120 | 8.7 | 1885 | −2.5 | 3 | 1.65 |
| 120 | 8.7 | 1885 | −2.6 | 3 | 1.84 |
| 120 | 8.7 | 1885 | −2.7 | 3 | 1.80 |
| 120 | 8.7 | 1885 | −2.8 | 3 | 1.80 |
| 120 | 8.7 | 1885 | −2.9 | 3 | 1.73 |
| 120 | 8.7 | 1305 | −2.7 | 3 | 1.82 |
| 120 | 8.7 | 2465 | −2.7 | 3 | 1.53 |
| 120 | 8.7 | 3045 | −2.7 | 3 | 1.43 |
| 120 | 10.2 | 1885 | −2.9 | 3 | 2.00 |
| 120 | 10.9 | 1885 | −2.9 | 3 | 2.76 |
| 120 | 11.6 | 1885 | −2.9 | 3 | 3.40 |
| 120 | 12.3 | 1885 | −2.9 | 3 | 4.30 |

In various implementations, resistance of printed patterns was characterized using a four-probe measurement platform (349701A, Keysight; DP281, RIGOL). Three consecutive layers may be deposited to form each film. Thickness of the printed patterns may be characterized with a white-light interferometry profilometer (Profilm3D, Filmetrics). In some examples, morphological characterization may be performed by scanning electron microscopy using a dual beam instrument (Helios G4 UC, Thermo Fisher Scientific) and by optical microscopy (BX53M, Olympus). In further examples, Fourier-transform infrared spectroscopy may be performed using a spectrometer (IRXross, Shimadzu) to assess chemical composition of the printed films. Reported values represent mean results, with error bars corresponding to standard deviation. Sample size for inset (b) and inset (c) of FIG. 11 may be n=5, while sample size for inset (g) and inset (h) of FIG. 11 may be n=3.

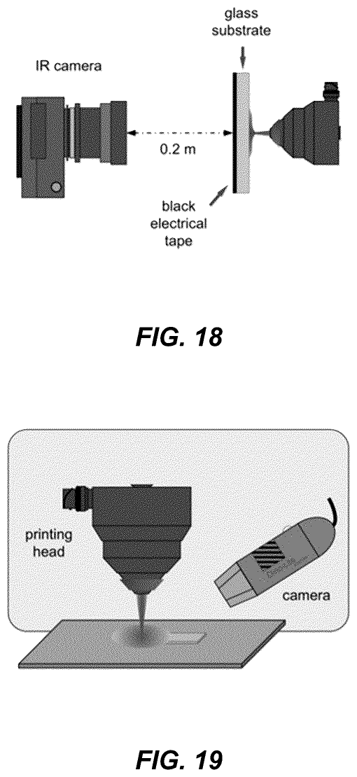

In some examples, thermal characterization of plasma sintering may be conducted using infrared imaging. FIG. 18 illustrates a schematic of an example thermal measurement apparatus. An infrared camera (FLIR T420) may be positioned approximately 0.2 m from the backside of a glass substrate to measure spatiotemporal temperature distributions. To reduce uncertainty associated with unknown emissivity of the substrate and to minimize interference from plasma-emitted infrared radiation, a layer of black electrical tape with an emissivity of approximately 0.92 and thickness of approximately 0.2 mm may be applied to the backside of the substrate. Previous validation indicated that temperature differences between the front and back surfaces of the substrate remained within the measurement uncertainty of the infrared camera, such that backside measurements approximate surface conditions at the plasma interaction region. Infrared image sequences may be collected at a rate of approximately 30 frames per second. In various implementations, temperature data presented in inset (c) of FIG. 10 exhibit an uncertainty of +2° C.

FIG. 19 is a schematic illustration of an example in-situ inspection setup. In various implementations, in situ detection and compensation during co-jet printing may be evaluated using the inspection configuration illustrated schematically in FIG. 19. An inspection camera (Dino-Lite Premier) is positioned above a substrate to acquire images at a frame rate of approximately one frame per second. Images are recorded on a computer system such as the control platform 116. The image data may be processed by software modules such as the supervisory application 136 configured to receive sensor signals and apply a machine learning model such as the machine learning model 138 for anomaly detection.

In some examples, the machine learning model such as the machine learning model 138 is implemented a PatchCore architecture trained using 18 samples fabricated under randomly varied printing and plasma jet parameters. During training, approximately 200 image frames from defect-free films are provided to a WideResNet-50 feature extractor within the model (e.g., feature extractor 308). Intermediate-level features may be aggregated to construct a feature bank such as the feature bank 310. A training utility such as the training application 140 applied coreset subsampling at approximately 5 percent sampling rate to retain critical information while reducing inference time and memory usage. During inference, features from test image patches are extracted in a manner consistent with training, and anomaly scores are computed by nearest-neighbor comparison to the feature bank 310. Training of the PatchCore implementation may be performed using the Anomalib 1.0 framework.

Validation of the anomaly detection method may be performed on a dataset comprising 10 frames from nominal deposition processes, 10 frames manually selected to represent plasma streamer formation, and 10 frames representing crack formation in printed films. Thresholds applied to anomaly scores may be determined by modules such as the supervisory application 136 to distinguish between nominal and anomalous conditions. In some examples, classification of a printed layer as cracked is based on a ratio of crack-suspected frames to total frames in that layer. Optimization of this threshold ratio to maximize prediction accuracy, measured by F1 score across the collected dataset, is performed using a training utility such as the training application 140.

In some examples, the co-jet printing system 100 may be implemented to deposit the hydration sensor on a leaf of a potted English ivy plant positioned on an electrically insulated printing platform. The leaf is secured on a flat surface. The nozzle drive 112 positions the nozzle assembly 108 to direct the aerosol stream and the plasma jet toward the leaf. The sheath gas supply 104 provides the sheath gas flow at approximately 120 sccm using argon. The carrier gas source 102 provides the carrier gas flow at approximately 10 sccm using argon. The working gas supply 106 provides the plasma working gas flow at approximately 1800 sccm using helium. The power supply 110 applies a plasma pulse voltage of approximately 2.2 kV across the electrodes 248 and 250. The nozzle drive 112 moves the nozzle assembly 108 at a printing speed of approximately 1 mm/s. The atomizer 234 receives an atomization voltage of approximately 30 V. The nozzle drive 112 directs the nozzle assembly 108 to print the electrode pattern with three passes.

In various implementations, an electrochemical workstation (Interface 1010E) measures impedance spectroscopy signals from the hydration sensor. The leaf with the printed hydration sensor is placed on an elevated flat surface, with edges of the leaf taped to the flat surface. Copper wires are bonded to wiring pads of the hydration sensor using silver paste and secured to the flat surface with tape. For the transient measurement in inset (g) of FIG. 16, the electrochemical workstation monitors the impedance continuously at a measurement frequency of approximately 10 kHz. A Savitzky-Golay filter smoothes the measured signal. A cold LED lamp (ES250UFO, Hytekgro) is placed above the plant as a supplemental light source.

### CONCLUSION

The foregoing description is merely illustrative in nature and does not limit the scope of the disclosure or its applications. The broad teachings of the disclosure may be implemented in many different ways. While the disclosure includes some particular examples, other modifications will become apparent upon a study of the drawings, the text of this specification, and the following claims. In the written description and the claims, one or more processes within any given method may be executed in a different order—or processes may be executed concurrently or in combination with each other—without altering the principles of this disclosure. Similarly, instructions stored in a non-transitory computer-readable medium may be executed in a different order—or concurrently—without altering the principles of this disclosure. Unless otherwise indicated, the numbering or other labeling of instructions or method steps is done for convenient reference and does not necessarily indicate a fixed sequencing or ordering.

It should also be noted that a plurality of hardware and software-based devices, as well as a plurality of different structural components may be utilized in various implementations. Aspects, features, and instances may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one instance, the electronic based aspects of the invention may be implemented in software (for example, stored on non-transitory computer-readable medium) executable by one or more processors. As a consequence, it should be noted that a plurality of hardware and software-based devices, as well as a plurality of different structural components may be utilized to implement the invention. For example, “control units” and “controllers” described in the specification can include one or more electronic processors, one or more memories including a non-transitory computer-readable medium, one or more input/output interfaces, and various connections (for example, a system bus) connecting the components.

Unless the context of their usage unambiguously indicates otherwise, the articles “a,” “an,” and “the” should not be interpreted to mean “only one.” Rather, these articles should be interpreted to mean “at least one” or “one or more.” Likewise, when the terms “the” or “said” are used to refer to a noun previously introduced by the indefinite article “a” or “an,” the terms “the” or “said” should similarly be interpreted to mean “at least one” or “one or more” unless the context of their usage unambiguously indicates otherwise.

It should also be understood that although certain drawings illustrate hardware and software located within particular devices, these depictions are for illustrative purposes only. In some embodiments, the illustrated components may be combined or divided into separate software, firmware, and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable connections or links.

Thus, in the claims, if an apparatus or system is claimed, for example, as including an electronic processor or other element configured in a certain manner, for example, to make multiple determinations, the claim or claim element should be interpreted as meaning one or more electronic processors (or other element) where any one of the one or more electronic processors (or other element) is configured as claimed, for example, to make some or all of the multiple determinations collectively. To reiterate, those electronic processors and processing may be distributed.

Spatial and functional relationships between elements—such as modules—are described using terms such as (but not limited to) “connected,” “engaged,” “interfaced,” and/or “coupled.” Unless explicitly described as being “direct,” relationships between elements may be direct or include intervening elements. The phrase “at least one of A, B, and C” should be construed to indicate a logical relationship (A OR B OR C), where OR is a non-exclusive logical OR, and should not be construed to mean “at least one of A, at least one of B, and at least one of C.” The term “set” does not necessarily exclude the empty set. For example, the term “set” may have zero elements. The term “subset” does not necessarily require a proper subset. For example, a “subset” of set A may be coextensive with set A, or include elements of set A. Furthermore, the term “subset” does not necessarily exclude the empty set.

In the figures, the directions of arrows generally demonstrate the flow of information—such as data or instructions. The direction of an arrow does not imply that information is not being transmitted in the reverse direction. For example, when information is sent from a first element to a second element, the arrow may point from the first element to the second element. However, the second element may send requests for data to the first element, and/or acknowledgements of receipt of information to the first element. Furthermore, while the figures illustrate a number of components and/or steps, any one or more of the components and/or steps may be omitted or duplicated, as suitable for the application and setting.

Additionally, operations (such as processes, decisions, inputs, outputs, actions, messages, interactions, events, and/or any other operations) shown in the flowcharts and/or message sequence charts may be illustrated once each and in a particular order in the drawings. However, in various implementations, the operations may be reordered and/or repeated as may be suitable. In some examples, different operations may be performed in parallel, as may be appropriate.

The term computer-readable medium does not encompass transitory electrical or electromagnetic signals or electromagnetic signals propagating through a medium-such as on an electromagnetic carrier wave. The term “computer-readable medium” is considered tangible and non-transitory. The functional blocks, flowchart elements, and message sequence charts described above serve as software specifications that can be translated into computer programs by the routine work of a skilled technician or programmer.

1. A coaxial nozzle assembly, comprising:
a nozzle body defining a longitudinal axis;
a central conduit extending through the nozzle body along the longitudinal axis, the central conduit having a first inlet and a first outlet;
a first outer annular flow channel extending through the nozzle body, the first outer annular flow channel concentrically surrounding the central conduit about the longitudinal axis, the first outer annular flow channel being radially outward from the longitudinal axis relative to the central conduit, the first outer annular flow channel having a second inlet and a second outlet;
a first electrode positioned radially opposed to a second electrode with respect to the longitudinal axis, the first electrode and the second electrode being positioned proximate the second outlet, a portion of the nozzle body being positioned between the first electrode and the outer annular flow channel, the portion of the nozzle body including a dielectric material;
an aerosol generator body positioned upstream of the nozzle body, the aerosol generator body having a third inlet and a third outlet, the third inlet and the third outlet being aligned with the longitudinal axis, the third outlet being fluidly coupled to the first inlet;
a first chamber formed in the aerosol generator body, the first chamber having a radius greater than a radius of the third inlet and a radius of the third outlet with respect to the longitudinal axis; and
a second outer annular flow channel extending through the aerosol generator body, the second outer annular flow channel concentrically surrounding the first chamber about the longitudinal axis, the second outer annular flow channel being radially outward from the longitudinal axis relative to the first chamber, the second outer annular flow channel having a fourth inlet and a fourth outlet.

2. The coaxial nozzle assembly of claim 1, wherein the second inlet has a radius greater than a radius of the second outlet, such that the first outer annular flow channel defines a first radially converging flow path toward the longitudinal axis.

3. The coaxial nozzle assembly of claim 1, wherein the fourth inlet has a radius greater than a radius of the fourth outlet, such that the second outer annular flow channel defines a second radially converging flow path toward the longitudinal axis.

4. The coaxial nozzle assembly of claim 3, further comprising a converging section formed in the aerosol generator body, the converging section being positioned between and fluidly coupling (i) the first chamber and the third outlet and (ii) the fourth outlet and the third outlet.

5. The coaxial nozzle assembly of claim 4, wherein the converging section defines an interior surface of the aerosol generator body tapering inward toward the longitudinal axis.

6. The coaxial nozzle assembly of claim 1, further comprising an atomizer in operative communication with the aerosol chamber.

7. The coaxial nozzle assembly of claim 5, wherein:
the third inlet and the first chamber define a first fluid path for a carrier gas flow;
the fourth inlet, second outer annular flow channel, and fourth outlet define a second fluid path for a sheath gas flow that concentrically surrounds and aerodynamically focus the carrier gas flow at the converging section to form an aerosol ink stream.
the fourth outlet, central conduit, and the first outlet define a third fluid path for the aerosol ink stream;
the second inlet, first outer annular flow channel, and second outlet define a fourth fluid path for a plasma working gas flow that is ionized by an electric potential applied across the first electrode and the second electrode to transition the plasma working gas flow into a near-ambient temperature plasma stream, the plasma stream substantially coaxially surrounding the aerosol ink stream as the aerosol ink stream exits the first outlet.

8. A method of forming and delivering an aerosol stream, comprising:
providing a carrier gas flow including atomized nanoparticles to a first inlet of an aerosol generator body, wherein the carrier gas flows from the first inlet to a first chamber formed in the aerosol generator body and expands within the first chamber;
providing a sheath gas flow to a second inlet of a first outer annular flow channel formed in the aerosol generator body, the first outer annular flow channel concentrically surrounding the first chamber, wherein the sheath gas flow is directed from a second outlet of the first outer annular flow channel to aerodynamically focus the expanded carrier gas flow and form a confined aerosol ink stream within a converging section positioned between the first chamber and a first outlet of the aerosol generator body;
delivering the aerosol ink stream from the first outlet of the aerosol generator body to a third inlet of a central conduit extending through a nozzle body, the aerosol ink stream exiting the nozzle body through a third outlet of the central conduit;
providing a plasma working gas flow to a fourth inlet of a second outer annular flow channel formed in the nozzle body, the second outer annular flow channel concentrically surrounding the central conduit;
applying an electric potential across a first electrode and a second electrode positioned proximate a fourth outlet of the second outer annular flow channel to ionize the plasma working gas flow and form a near-ambient temperature plasma stream, the plasma stream exiting the fourth outlet and substantially coaxially surrounding the aerosol ink stream.

9. The method of claim 8, further comprising positioning the nozzle body to direct the aerosol ink stream and the plasma stream toward a substrate to facilitate sintering of nanoparticles of the aerosol ink stream upon deposition at the substrate.

10. The method of claim 8, wherein the electric potential is a pulsed voltage generated using a voltage pulse generator, the pulsed voltage exceeding a breakdown threshold of the plasma working gas.

11. The method of claim 8, further comprising generating, at an atomizer positioned in operative communication with the first chamber, ultrasonic waves that induce pressure fluctuations in the expanded carrier gas flow.

12. The method of claim 8, wherein the carrier gas flow includes an inert gas transporting atomized nanoparticles from an upstream aerosolization source to the first inlet.

13. The method of claim 8, wherein the atomized nanoparticles include metal nanoparticles, metal oxide nanoparticles, semiconductor nanoparticles, quantum dot nanoparticles, dielectric nanoparticles, carbon-based nanoparticles, biologically active nanoparticles, polymeric nanoparticles, or a combination thereof.

14. The method of claim 8, wherein the plasma working gas flow includes a substantially inert gas that forms a plurality of plasma streamers when ionized by the electric potential.

15. A system, comprising:
non-transitory computer-readable storage media storing instructions; and
an electronic processor configured to execute the instructions to:
receive, from a live inspection camera, an image frame capturing deposition of an aerosol ink stream onto a substrate, the aerosol ink stream being coaxially surrounded by a plasma stream, the plasma stream being at a near-ambient temperature,
segment the image frame to define a plasma jet region, the plasma jet region corresponding to a portion of the image frame including the plasma stream,
provide the image frame to a machine learning model to generate a pixel-level anomaly heatmap comprising a plurality of pixel values, each pixel value being indicative of a likelihood of an anomaly at a corresponding location in the image frame,
determine a plasma jet region anomaly score based on pixel values of the anomaly heatmap within the plasma jet region,
in response to determining that the plasma jet region anomaly score exceeds a first threshold, reduce a voltage applied to electrodes of a coaxial nozzle assembly configured to generate the plasma stream, and
in response to determining that the plasma jet region anomaly score does not exceed the first threshold, increase the voltage applied to the electrodes.

16. The system of claim 15, wherein the electronic processor is further configured to execute the instructions to:
segment the image frame to define a printed film region, the printed film region corresponding to a portion of the image frame representing a deposited film on the substrate;
determine a printed film region anomaly score based on pixel values of the anomaly heatmap within the printed film region; and
in response to determining that the printed film region anomaly score exceeds a second threshold, mark the image frame as anomalous.

17. The system of claim 16, wherein the electronic processor is further configured to execute the instructions to:
compute an anomaly ratio based on a ratio of image frames marked as anomalous to a total number of image frames captured during a printing pass; and
in response to determining that the anomaly ratio exceeds a third threshold, initiate a repair action.

18. The system of claim 17, wherein the electronic processor is further configured to execute the instructions to initiate the repair action by:
printing a first new layer on the substrate with the plasma stream disabled by withholding voltage from the electrodes; and
printing a second new layer over the first new layer with the plasma stream enabled by applying a pulsed voltage to the first electrode and the second electrode that exceeds a breakdown threshold of a plasma working gas.

19. The system of claim 15, wherein the machine learning model is trained using a training dataset consisting of unlabeled image frames representing non-anomalous conditions.

20. The system of claim 19, wherein the machine learning model comprises:
a convolutional neural network configured to extract feature vectors from the image frame, the feature vectors representing a collection of local patches from the image frame;
a memory bank storing a subset of feature vectors representing nominal patches from the training dataset; and
nearest-neighbor comparison logic configured to compute, for each test patch, an anomaly score based on a distance between the feature vector for the test patch and a nearest feature vector in the memory bank.
